(19) United States
(12) Patent Application Publication
(10) Pub. No.: US 2024/0055272 A1
(43) Pub. Date: Feb. 15, 2024

(54) METHOD FOR PROCESSING SEMICONDUCTOR CONTAINING TRANSITION METAL, METHOD FOR PRODUCING SEMICONDUCTOR CONTAINING TRANSITION METAL, AND PROCESSING LIQUID FOR SEMICONDUCTORS

(71) Applicant: TOKUYAMA CORPORATION, Yamaguchi (JP)

(72) Inventors: Yuki KIKKAWA, Yamaguchi (JP); Tomoaki SATO, Yamaguchi (JP); Kohei SAITO, Yamaguchi (JP); Hiroto YARIMIZU, Yamaguchi (JP); Takayuki NEGISHI, Yamaguchi (JP)

(73) Assignee: TOKUYAMA CORPORATION, Yamaguchi (JP)

(21) Appl. No.: 18/269,195

(22) PCT Filed: Dec. 20, 2021
(86) PCT No.: PCT/JP2021/047028

§ 371 Date: Jun. 22, 2023

(30) Foreign Application Priority Data
Dec. 25, 2020 (JP) 2020-216867
Mar. 31, 2021 (JP) 2021-062341

(51) Int. Cl. H01L 21/3213; H01L 21/02; H01L 21/66

(52) U.S. Cl. CPC H01L 21/32134; H01L 21/02068; H01L 22/12

(57) ABSTRACT

An object of the present invention is to provide a method for producing a semiconductor containing a transition metal with a flat surface, by suppressing loss of flatness (surface roughening) of the transition metal surface, which is caused by anisotropic etching resulting from different etching rates among different crystal planes of the transition metal during etching of the transition metal film with crystal planes of various orientations exposed at the surface. According to the present invention, the problem is solved by any one of the following: a processing method for a semiconductor containing a transition metal, the method including a step of etching the transition metal at an etching amount ratio of 0.1 or greater and 10 or less, the etching amount ratio being a ratio of an etching amount in one crystal plane of the transition metal to an etching amount in another crystal plane of the transition metal; a processing method for a semiconductor containing a transition metal, the method including etching the transition metal, and measuring an etching amount ratio of the transition metal; and a processing liquid for semiconductors, the processing liquid containing an amphoteric surfactant or an amine, the amphoteric surfactant being betaine, imidazoline, glycine or an amine oxide.

### TECHNICAL FIELD

The present invention relates to a method for processing a semiconductor containing a transition metal, a method for producing a semiconductor element including a step of etching a transition metal, and a semiconductor processing liquid for etching a transition metal.

### BACKGROUND ART

Transition metals are widely used in electronic devices, such as semiconductor elements, and are used, for example, in contact materials that connect the electrode of a transistor to a metal wiring and in gate materials for 3D-NANDs.

When a transition metal is selected as a wiring material in a wiring formation process of a semiconductor element, the wiring is formed by dry or wet etching and by CMP polishing, as well as typical wiring materials. The time required for these processes directly affects semiconductor manufacturing costs, and thus there is a demand for a technique that can reduce the treatment time.

In order to adopt a transition metal in fine wiring, the etching rate of the transition metal must be accurately controlled. Further, flatness of each transition metal layer is essential for realizing multilayer wiring, and flatness of the transition metal surface after etching is also desired. As a technique for carrying out such high precision etching, dry etching in which a metal film is processed using a gas or wet etching in which a metal film is processed using a chemical solution is used.

Patent Document 1 proposes, as a method for etching with high precision while inhibiting and reducing surface roughness of the transition metal film, a method of etching a transition metal film containing a transition metal element such as Co or Ru using a complexation gas.

### PRIOR ART DOCUMENTS

### Patent Documents

Patent Document 1: WO 2020/157954 A1

### SUMMARY OF INVENTION

### Technical Problem

The etching method described in Patent Document 1 is divided into steps of oxidation and etching using a complexation gas. The oxidation step and the etching step are set as one cycle, and this cycle is repeated to control the etching amount. However, it is difficult to isotropically oxidize the surface in the oxidation step, and the flatness of the surface obtained in the subsequent etching step is insufficient.

On the other hand, the transition metal film is a polycrystal composed of a large number of fine single crystals, and the crystal planes exposed on the surface of the transition metal film are of various orientations. Through an investigation by the present inventors, it became clear that when the transition metal film is etched, anisotropic etching in which the etching rate differs for each crystal plane of the transition metal is exhibited. It was also found that unevenness is generated due to the difference in the etching rate at each crystal plane, and this unevenness is a cause of a deterioration in flatness of the transition metal surface after etching.

Accordingly, an object of the present invention is to provide a method for processing a surface of a transition metal semiconductor such that the surface becomes flat by suppressing surface roughness caused by anisotropic etching in which the etching rate differs at each crystal plane of the transition metal when a transition metal film having crystal planes of various orientations exposed at the surface is etched, and also to provide a method for producing a transition metal semiconductor having a flat surface.

### Solution to Problem

The present inventors conducted diligent research to solve the above problems. Through this research, the present inventors discovered that the flatness of the surface of the transition metal after etching can be maintained by etching the transition metal at an etching amount ratio of 0.1 or greater and 10 or less, the etching amount ratio being a ratio of an etching amount in one crystal plane of the transition metal to an etching amount in another crystal plane of the transition metal. The present inventors also discovered that the flatness of the surface of the transition metal after etching can be maintained by etching the transition metal with a semiconductor processing liquid containing an amphoteric surfactant or an amine, wherein the amphoteric surfactant is betaine, imidazoline, glycine, or an amine oxide, and thereby the present inventors arrived at the present invention.

That is, the present invention is configured as follows.

Aspect 1. A method for processing a semiconductor containing a transition metal, the method including a step of etching the transition metal at an etching amount ratio of 0.1 or greater and 10 or less, the etching amount ratio being a ratio of an etching amount in one crystal plane of the transition metal to an etching amount in another crystal plane of the transition metal.

Aspect 2. The processing method according to aspect 1, including the step of etching and a step of washing with a solvent or with a solution containing a surfactant or a transition metal-coordinating ligand.

Aspect 3. The processing method according to aspect 1 or 2, wherein the transition metal is ruthenium.

Aspect 4. The processing method according to aspect 3, wherein the step of etching is a step of etching ruthenium at an etching amount ratio of 0.1 or greater and 10 or less, the etching amount ratio being a ratio of an etching amount in one crystal plane selected from the group consisting of ruthenium (002), ruthenium (100), ruthenium (101), ruthenium (110), ruthenium (102), ruthenium (103), ruthenium (200), ruthenium (112) and ruthenium (201) to an etching amount in another crystal plane different from the crystal plane selected from the group.

Aspect 5. A method for processing a ruthenium semiconductor, the method including a step of etching ruthenium at an etching amount ratio of 0.1 or greater and 10 or less, the etching amount ratio being a ratio of an etching amount in ruthenium (002) to an etching amount in one crystal plane of the crystal planes of ruthenium excluding ruthenium (002).

Aspect 6. The processing method according to any one of aspects 3 to 5, wherein in the step of etching, an etching rate of one crystal plane of the crystal planes of ruthenium excluding ruthenium (002) is set to 1 nm/min or greater and 100 nm/min or less.

Aspect 7. The processing method according to aspect 5 or 6, wherein the one crystal plane of the crystal planes of ruthenium excluding ruthenium (002) is ruthenium (101) or ruthenium (100).

Aspect 8. The processing method according to any one of aspects 1 to 7, wherein the step of etching is performed by wet etching using an etching solution.

Aspect 9. The processing method according to aspect 8, wherein the etching solution contains an onium ion.

Aspect 10. The processing method according to aspect 9, wherein the onium ion is an ammonium ion.

Aspect 11. The processing method according to any one of aspects 8 to 10, wherein the etching solution contains an oxidizing agent.

Aspect 12. The processing method according to aspect 11, wherein a concentration of the oxidizing agent in the etching solution is 0.001 mol/L or greater and 1 mol/L or less.

Aspect 13. The processing method according to aspect 11 or 12, wherein the oxidizing agent is a halogen oxyacid, a halogen oxyacid ion, a halogen oxyacid salt, a permanganic acid, a permanganate ion, a permanganate salt, a cerium (1V) salt, a ferricyanide salt, hydrogen peroxide or ozone.

Aspect 14. The processing method according to aspect 13, wherein the halogen oxyacid ion is a hypobromite ion, and a pH of the etching solution at 25° C. is 8 or greater and 12 or less.

Aspect 15. The processing method according to any one of aspects 8 to 14, wherein the etching solution contains:
at least one type of hypohalite ion; and
at least one type of anionic species selected from a halate ion, a halite ion, and a halide ion, and
a content of at least one type of anionic species of the anionic species is 0.30 mol/L or greater and 6.00 mol/L or less.

Aspect 16. The processing method according to aspect 1, further including a step of removing a transition metal oxide generated by the step of etching.

Aspect 17. The processing method according to aspect 16, wherein the step of removing the transition metal oxide is a step of washing with a solvent or with a solution containing a surfactant or a transition metal-coordinating ligand.

Aspect 18. The processing method according to aspect 16 or 17, wherein the metal is ruthenium.

Aspect 19. A method for processing a semiconductor containing a transition metal, the method including: a step of etching the transition metal; and a step of measuring an etching amount ratio, the etching amount ratio being a ratio of an etching amount in one crystal plane of the transition metal to an etching amount in another crystal plane of the transition metal.

Aspect 20. The processing method according to aspect 19, wherein the step of measuring the etching amount ratio of an etching amount in one crystal plane of the transition metal to an etching amount in another crystal plane of the transition metal is a step in which an X-ray diffraction measurement is used.

Aspect 21. A method for producing a semiconductor containing a transition metal, the method including the processing method according to any one of aspects 1 to 20.

Aspect 22. A processing liquid for a semiconductor, the processing liquid containing an amphoteric surfactant or an amine, the amphoteric surfactant being betaine, imidazoline, glycine or an amine oxide.

Aspect 23. The processing liquid according to aspect 22, wherein the processing liquid contains an oxidizing agent.

Aspect 24. The processing liquid according to aspect 23, wherein the oxidizing agent is a halogen oxyacid, a halogen oxyacid ion, a halogen oxyacid salt, a permanganic acid, a permanganate ion, a permanganate salt, a cerium (IV) salt, a ferricyanide salt, hydrogen peroxide or ozone.

Aspect 25. The processing liquid according to aspect 23 or 24, wherein the processing liquid etches ruthenium, tungsten, molybdenum, cobalt, or chromium.

### Effects of Invention

According to the present invention, in a process for producing a semiconductor containing a transition metal, a transition metal film included in a semiconductor wafer can be isotropically etched by etching the transition metal at an etching amount ratio of 0.1 or greater and 10 or less, the etching amount ratio being a ratio of an etching amount in one crystal plane of the transition metal to an etching amount in another crystal plane of the transition metal. Further, by processing a semiconductor wafer with a semiconductor processing liquid containing an amphoteric surfactant or an amine, where the amphoteric surfactant is betaine, imidazoline, glycine, or an amine oxide, a transition metal oxide produced during etching can be removed, and a transition metal film contained in the semiconductor wafer can be isotropically etched. As a result, the flatness of the transition metal surface after the etching treatment can be maintained. Therefore, the present invention can be suitably used for forming a semiconductor element having a multilayer wiring structure for which flatness of each layer is required.

### DESCRIPTION OF EMBODIMENTS

A method for processing a semiconductor containing a transition metal, and a processing liquid for a semiconductor according to the present invention will be described below in order.

### (Semiconductor Containing Transition Metal)

In the present invention, a semiconductor containing a transition metal refers to a transition metal-containing semiconductor used for a wiring layer, a barrier layer, a liner layer, a cap layer, a plug layer, or the like formed as a film on a semiconductor wafer. Examples of the transition metal in the present invention include ruthenium, cobalt, copper, molybdenum, chromium, tungsten, aluminum, nickel, and manganese. The processing method of the present invention is particularly effective in etching treatment of ruthenium, tungsten, molybdenum, cobalt, or chromium used in a fine wiring process requiring flatness after etching, and is most effective in etching treatment of ruthenium.

In the present invention, the transition metal contained in a semiconductor wafer can be formed by any method. For the formation of a transition metal film, a method widely known in a semiconductor manufacturing process can be used, including, for example, CVD, ALD, PVD, sputtering, or plating.

These transition metals can be in a form of an oxide, a nitride, a silicide, a carbide, an intermetallic compound, an ionic compound, or a complex. In addition, the transition metal can be exposed at the surface of the wafer or can be partially covered with another metal, a metal oxide film, an insulating film, a resist, or the like. In the present invention, these transition metals are polycrystals having at least two or more crystal planes.

### (Ruthenium Contained in Semiconductor Wafer)

In a particularly preferable embodiment of the present invention, the transition metal is ruthenium. Hereinafter, a semiconductor containing ruthenium is referred to as a ruthenium semiconductor. In the present embodiment, ruthenium is a polycrystal having at least two or more crystal planes.

In the present embodiment, the ruthenium contained in a semiconductor wafer can be formed by any method. For the formation of a ruthenium film, a method widely known in a semiconductor manufacturing process can be used, including, for example, CVD. ALD, PVD, sputtering, or plating.

In the present embodiment, the ruthenium includes an elemental metal ruthenium including a crystal plane selected from ruthenium (002), ruthenium (100), ruthenium (101), ruthenium (110), ruthenium (102), ruthenium (103), ruthenium (200), ruthenium (112), or ruthenium (201) and at least one crystal plane other than the selected crystal plane, and in addition thereto, can include a ruthenium metal partially containing ruthenium, an oxide, a nitride (RuN), or the like. Here, the notation of ruthenium (002) or the like means a ruthenium 002 plane or the like. In addition, a ruthenium alloy can also be contained, which contains ruthenium and other metal than ruthenium at a concentration higher than a concentration at which the other metal is unavoidably contained.

The ruthenium alloy can contain any metal other than ruthenium. Examples of the metal contained in the ruthenium alloy include tantalum, silicon, copper, hafnium, zirconium, aluminum, vanadium, cobalt, nickel, manganese, gold, rhodium, palladium, titanium, tungsten, molybdenum, platinum, and iridium, and the ruthenium alloy can contain an oxide, a nitride, a carbide, or a silicide of a metal of these.

These rutheniums can be an intermetallic compound, an ionic compound, or a complex. In addition, the ruthenium can be exposed at the surface of the wafer or covered partially with another metal, a metal oxide film, an insulating film, a resist, or the like.

### (Etching Amount Ratio)

In the present invention, the etching amount ratio represents a ratio of a change rate of one crystal plane of the transition metal to a change rate of another crystal plane of the transition metal in association with etching. Here, the change rate is a value obtained by dividing the amount of the crystal plane etched by the etching treatment by the amount of the crystal plane before the etching treatment, and converting the result to a percentage. That is, when two arbitrary crystal planes of the transition metal are selected, the change rate is a value obtained by dividing the change rate of one crystal plane by the change rate of the other crystal plane. Therefore, an etching amount ratio of 1 means that the change rates of the two selected crystal planes are the same, and means that the presence ratios of the two crystal planes are the same (not changed) even after the etching treatment. An etching amount ratio that is not 1 means that the change rate of one of the two crystal planes is larger than that of the other. When the transition metal has a plurality of crystal planes, a plurality of etching amount ratios can be defined, but at least one etching amount ratio needs to be 0.1 or greater and 10 or less. The method for determining the etching amount ratio is not particularly limited, and examples thereof include a method in which the change rate in a diffraction peak area of each of two crystal planes is determined from X-ray diffraction (XRD) measurements of the transition metal, and the etching amount ratio is calculated.

When the transition metal is etched at an etching amount ratio of 0.1 or greater and 10 or less, the etching ratio being a ratio of an etching amount in one crystal plane of the transition metal to an etching amount in another crystal plane of the transition metal as determined in an X-ray diffraction of the transition metal, the difference in etching rates between one crystal plane and another crystal plane becomes small. As a result, unevenness of the transition metal surface caused by the difference in etching rates becomes small. Therefore, the most preferable state is when the etching amount ratio of one crystal plane to another crystal plane is 1, and such an etching amount ratio indicates that the flatness is maintained even after the etching treatment. The degree of flatness to be allowed depends on the process in which the transition metal is to be used, but particularly in a process in which flatness of the transition metal surface after etching is required, etching is preferably carried out at an etching amount ratio of one crystal plane to another crystal plane of 0.1 or greater and 10 or less, more preferably at 0.2 or greater and 5 or less, even more preferably 0.3 or greater and 3 or less, yet even more preferably 0.5 or greater and 2 or less, and most preferably 0.8 or greater and 1.2 or less.

A case in which the transition metal is ruthenium and includes crystal planes of ruthenium (002), ruthenium (100), ruthenium (101), ruthenium (110), ruthenium (102), ruthenium (103), ruthenium (200), ruthenium (112), or ruthenium (201) will be exemplified below. In this case, as the etching amount ratio approaches 1, where the etching amount ratio is a ratio of an etching amount in one crystal plane selected from the group consisting of ruthenium (002), ruthenium (100), ruthenium (101), ruthenium (110), ruthenium (102), ruthenium (103), ruthenium (200), ruthenium (112) and ruthenium (201) to an etching amount in another crystal plane different from the crystal plane selected from the group, the difference in the etching rates between the crystal plane selected from the group consisting of ruthenium (002), ruthenium (100), ruthenium (101), ruthenium (110), ruthenium (102), ruthenium (103), ruthenium (200), ruthenium (112) and ruthenium (201) to the other crystal plane than the crystal plane selected from the group becomes small. As a result, unevenness of the ruthenium surface caused by the difference in etching rates becomes small, resulting in high flatness. Therefore, the etching amount ratio is most preferably 1, where the etching amount ratio is an etching amount ratio of one crystal plane selected from the group consisting of ruthenium (002), ruthenium (100), ruthenium (101), ruthenium (110), ruthenium (102), ruthenium (103), ruthenium (200), ruthenium (112) and ruthenium (201) to the other crystal plane than the crystal plane selected from the group. The degree of flatness to be allowed depends on the process in which the ruthenium is to be used, but particularly in a process in which flatness of the ruthenium surface after etching is required, etching is preferably carried out at an etching amount ratio 0.1 or greater and 10 or less, more preferably at 0.2 or greater and 5 or less, even more preferably 0.3 or greater and 3 or less, yet even more preferably 0.5 or greater and 2 or less, and most preferably 0.8 or greater and 1.2 or less, where the etching amount ratio is an etching amount ratio of one crystal plane selected from the group consisting of ruthenium (002), ruthenium (100), ruthenium (101), ruthenium (110), ruthenium (102), ruthenium (103), ruthenium (200), ruthenium (112) and ruthenium (201) to the other crystal plane than the crystal plane selected from the group.

The term “flatness” as used herein refers to surface roughness, and high flatness or low surface roughness means that the surface has little unevenness. Maintaining flatness means that the flatness does not change before and after a chemical solution treatment. The flatness can be evaluated by, for example, observation under an electron microscope or measurements using an atomic force microscope.

When the transition metal is ruthenium, the crystal plane selected from ruthenium (002), ruthenium (100), ruthenium (101), ruthenium (110), ruthenium (102), ruthenium (103), ruthenium (200), ruthenium (112), and ruthenium (201) used for calculating the etching amount ratio is not particularly limited, but is preferably a crystal plane having the highest X-ray diffraction intensity. Among the above crystal planes, from the perspectives of a high relative intensity of the X-ray diffraction and facilitation of crystal growth, ruthenium (002), ruthenium (100), and ruthenium (101) are preferable, and ruthenium (002) is more preferable. The other crystal plane than the crystal plane selected from the group is not particularly limited, but is preferably a crystal plane having the second highest X-ray diffraction intensity.

A case in which the transition metal is molybdenum and includes a crystal plane of molybdenum (110), molybdenum (211), molybdenum (200), or molybdenum (220) will be exemplified below. In this case, as the etching amount ratio approaches 1, where the etching amount ratio is a ratio of an etching amount in one crystal plane selected from the group consisting of molybdenum (110), molybdenum (211), molybdenum (200), and molybdenum (220) to an etching amount in another crystal plane different from the crystal plane selected from the group, the difference in etching rates between the one crystal plane selected from the group consisting of molybdenum (110), molybdenum (211), molybdenum (200), and molybdenum (220) to the other crystal plane different from the one crystal plane selected from the group becomes small. As a result, unevenness of the molybdenum surface caused by the difference in etching rates becomes small, and the flatness increases. Therefore, the etching amount ratio is most preferably 1, where the etching amount ratio is an etching amount ratio of one crystal plane selected from the group consisting of molybdenum (110), molybdenum (211), molybdenum (200), and molybdenum (220) to the other crystal plane than the crystal plane selected from the group. The degree of flatness to be allowed depends on the process in which the molybdenum is to be used, but particularly in a process in which flatness of the molybdenum surface after etching is required, etching is preferably carried out at an etching amount ratio of 0.1 or greater and 10 or less, more preferably at 0.2 or greater and 5 or less, even more preferably 0.3 or greater and 3 or less, yet even more preferably 0.5 or greater and 2 or less, and most preferably 0.8 or greater and 1.2 or less, where the etching amount ratio is an etching amount ratio of one crystal plane selected from the group consisting of molybdenum (110), molybdenum (211), molybdenum (200), and molybdenum (220) to the other crystal plane than the crystal plane selected from the group.

When the transition metal is molybdenum, the crystal plane selected from the group consisting of molybdenum (110), molybdenum (211), molybdenum (200), and molybdenum (220) used for calculating the etching amount ratio is not particularly limited, but is preferably a crystal plane having the highest X-ray diffraction intensity. Among the above-mentioned crystal planes, from the perspectives of a high relative intensity of the X-ray diffraction and facilitation of crystal growth, molybdenum (110) and molybdenum (211) are preferable, and molybdenum (110) is more preferable. The other crystal plane than the crystal plane selected from the group is not particularly limited, but is preferably a crystal plane having the second highest X-ray diffraction intensity.

### (Etching Rate)

In general, the etching rate of a transition metal is affected by many factors, such as the film formation method, the film thickness, the crystallinity (crystal system, lattice constant, etc.), the crystal grain size, lattice defects, the impurity content, the oxidation state, and the presence or absence of a surface oxide film. The etching rate also depends on the plane orientation of the crystal plane in contact with the etching solution. The crystal plane dependency of transition metal etching varies dependent on the transition metal, but when a plurality of crystal planes are in contact with the etching solution, the etching rate often varies dependent on the crystal plane. In such a case, the difference in etching rate dependent on the crystal plane appears as unevenness of the transition metal surface. This is because the crystal plane having a high etching rate is etched more in the etching treatment than the crystal plane having a low etching rate. As a result, the flatness of the surface of the transition metal film after the etching treatment is not maintained, and unevenness of the surface increases. Therefore, in order to maintain the flatness of the transition metal surface after the etching treatment, the change rate between the crystal planes is preferably made uniform. The plane orientation dependence of etching varies depending on the transition metal to be etched, but in order to make the change rate between crystal planes uniform, etching conditions such as the composition and pH of the etching solution can be controlled so that the etching rates between crystal planes are the same. For example, when the concentration of the oxidizing agent is increased, the etching rate is increased, but etching of the crystal plane that is easily etched is accelerated, and therefore the surface roughness that is dependent on the etching rate difference is increased. At this time, the etching rate is decreased by increasing the pH. That is, the etching rate of the crystal plane that is easily etched is suppressed, and the surface roughness that is dependent on the etching rate difference is accordingly suppressed. As described above, the surface roughness can be suppressed by controlling the concentration of the oxidizing agent and the pH within appropriate ranges using the etching rate ratio of each crystal plane as an indicator. In addition, the etching rate of the crystal plane that is easily etched can also be suppressed by adding an additive that is selectively adsorbed to the crystal plane having a high etching rate, and thus the etching rate of each crystal plane can be controlled and the surface roughness can be suppressed by appropriately adding the additive using the etching rate ratio of each crystal plane as an indicator. The rate at which the transition metal is etched can be determined, as appropriate, with consideration of the type of transition metal, the amount of etching, the etching time, and the like, and the etching rate of any one of the crystal planes of the transition metal can be set to be 0.1 times or more and 10.0 times or less the etching rate of the other crystal plane. Such an etching rate is preferably 0.1 nm/min or greater and 1000 nm/min or less, and more preferably 1 nm/min or greater and 100 nm/min or less.

In general, the etching rate of a crystal plane of ruthenium excluding ruthenium (002) is slower than the etching rate of ruthenium (002), and thus it is difficult to etch the crystal plane of ruthenium excluding ruthenium (002). Therefore, in a ruthenium film including ruthenium (002) and a crystal plane of ruthenium other than ruthenium (002), a difference occurs in the etching amount depending on the crystal plane of ruthenium. As a result, the etching amount ratio deviates from the above-described suitable range, and thus the flatness tends to be low.

In one preferred embodiment of the present invention, the etching rate of the crystal plane of ruthenium excluding ruthenium (002) is accelerated, and thereby the difference from the etching rate of ruthenium (002) is reduced, and the etching amount ratio dependent on the crystal plane of ruthenium approaches 1. For example, the difference from the etching rate of ruthenium (002) can be reduced by setting the etching rate of any one of the crystal planes of ruthenium excluding ruthenium (002) to 1 nm/min or greater and 100 nm/min or less, and as a result, a decrease in flatness can be suppressed. In particular, in a process in which flatness of a ruthenium surface after etching treatment is required, the etching rate of any one of the crystal planes of ruthenium excluding ruthenium (002) is preferably 1 nm/min or greater and 100 nm/min or less, more preferably 3 nm/min or greater and 50 nm/min or less, even more preferably 4 nm/min or greater and 20 nm/min or less, and most preferably 5 nm/min or greater and 10 nm/min or less. The etching rate of ruthenium is increased by at least one of increasing the concentration of the oxidizing agent, decreasing the pH, and increasing the treatment temperature. On the other hand, the etching rate of ruthenium is decreased by at least one of decreasing the concentration of the oxidizing agent, increasing the pH, decreasing the treatment temperature, and adding an additive that is adsorbed to ruthenium and inhibits etching. An etching solution having a desired etching rate can be prepared by appropriately controlling at least one of the concentration of the oxidizing agent, the pH, the temperature, and the additive concentration.

### [Washing Step]

The present invention can include a step of washing the wafer before and/or after the etching treatment. When a state continues in which a transition metal oxide dissolved in the etching solution is present in the vicinity of the transition metal surface due to the etching treatment, the transition metal oxide may adhere to the transition metal surface or may react with the transition metal surface to form another transition metal oxide that is deposited. Further, when a solid transition metal oxide generated by etching remains on the wafer surface or in the vicinity of the wafer surface, the solid transition metal oxide may adhere as particles to the transition metal. Adhesion or deposition of the transition metal oxide on the transition metal surface is not preferable because it causes the flatness of the transition metal surface to be impaired. The time during which the transition metal oxide generated by etching is present in the etching solution in the vicinity of the transition metal surface can be reduced by providing the step of washing the wafer after the etching treatment of the transition metal, and therefore adhesion or deposition of the transition metal oxide to the transition metal surface can be easily prevented, and the flatness of the transition metal surface can be easily maintained.

Further, when diffusivity of the transition metal oxide generated in the etching solution is poor, the transition metal oxide may be deposited on the transition metal surface during etching. In order to prevent this, preferably, washing is carried out after etching under conditions in which deposition of the transition metal oxide on the transition metal surface does not occur, or the deposition amount of the transition metal oxide on the transition metal surface falls within an allowable range, and then etching is carried out once again. By including a step of washing, even a transition metal oxide having poor diffusivity can be easily kept away from the transition metal surface, and deposition of the transition metal oxide can be prevented.

Further, a step of washing can be included before the etching treatment. By including a step of washing before the etching treatment, the wettability of the transition metal to be etched can be controlled, and the etching solution can be more evenly spread over the surface of the transition metal. Evenly spreading the etching solution over the surface of the transition metal eliminates positional dependence (local unevenness) of etching, and the flatness of the surface is easily maintained. Furthermore, in a case in which a solvent or a solution containing a surfactant or a transition metal-coordinating ligand is used as a washing liquid described below, a state in which these solvent molecules, the surfactant, or the ligand is present on the transition metal surface through coordinate bonding with the transition metal, electrostatic interaction, or the like, can be created. These solvent molecules, the surfactant, or the ligand on the transition metal surface act to inhibit adsorption or deposition of the transition metal oxide described above. As a result, by etching after washing with a solvent or a solution containing a surfactant or a transition metal-coordinating ligand, deposition and adsorption of a transition metal oxide on the transition metal surface are suppressed, and the flatness of the transition metal surface is easily maintained. Of course, the step of washing the wafer can be carried out before and after the etching treatment, and the above-described effect can be obtained.

The conditions for washing the wafer are not particularly limited, and widely known washing methods and conditions used in semiconductor manufacturing can be used, and can be appropriately determined with consideration of the type, chemical state, or structure of the transition metal to be etched, the concentration or diffusivity of the transition metal oxide in the etching solution, the etching amount, the ease of deposition, and the like. That is, the washing method, time, temperature, and the like can be appropriately selected. In addition, the washing can be single wafer washing, immersion in a washing liquid, washing with application of ultrasonic waves or a jet flow, scrub washing, or manual washing or automatic washing.

In addition, the order of the steps of etching and washing is not particularly limited, and each step can be independently performed any number of times. The number of times of these steps can be appropriately determined in consideration of the type, chemical state or structure of the transition metal to be etched, the concentration or diffusivity of the transition metal oxide in the etching solution, the amount of etching, the ease of deposition, and the like. That is, the step of washing the wafer can be implemented one or more times. In addition, when the washing step is included a plurality of times, the washing liquid used for washing can be the same or different.

### (Washing Liquid)

The washing liquid used in the washing step can be any washing liquid as long as the washing liquid is a solvent or solution that interacts with the transition metal surface to be etched, or is a solvent or solution that can remove the transition metal oxide from the surface of the transition metal or the vicinity of the wafer surface.

The solvent or solution that interacts with the transition metal surface to be etched is, for example, a solvent capable of interacting with the transition metal surface to form a layer of solvent molecules on the transition metal surface, or a solution containing molecules or ions such as a surfactant or ligand that is adsorbed or coordinated to the transition metal surface. By washing using such a solvent or solution, a layer of solvent molecules, surfactant, or ligands is formed on the transition metal surface, and adsorption and deposition of the transition metal oxide is inhibited. As a result, even when an oxide of the transition metal is generated during the etching treatment of the transition metal, adsorption and deposition of the transition metal oxide on the transition metal surface can be prevented, and the flatness of the transition metal film is maintained.

The solvent or solution that can remove the transition metal oxide from the surface of the transition metal or the vicinity of the wafer surface is, for example, a solvent or solution that can dissolve the transition metal oxide, can prevent the transition metal oxide from re-adhering, or can wash away the transition metal oxide.

The transition metal oxide is rapidly dissolved and diluted by using a solvent or solution that can dissolve the transition metal oxide, and thereby the concentration of the transition metal oxide in the vicinity of the transition metal surface or in the vicinity of the wafer surface can be reduced. As a result, deposition or adhesion of an oxide to the transition metal surface is less likely to occur, and thus the flatness of the transition metal film is maintained.

The solvent or solution that can prevent the transition metal oxide from re-adhering is, for example, a solvent capable of interacting with the transition metal oxide surface to form a layer of solvent molecules on the transition metal oxide surface, or a solution containing molecules or ions such as a surfactant or ligand that is adsorbed or coordinated to the transition metal oxide surface. By washing using these solvents or solutions, a layer of solvent molecules, surfactant, or ligands is formed on the transition metal oxide surface, and adsorption and deposition of the transition metal oxide on the transition metal surface is inhibited. As a result, the flatness of the transition metal film is maintained even when an oxide of the transition metal is generated during the etching treatment of the transition metal.

By using a solvent or a solution capable of washing away the transition metal oxide, the transition metal oxide generated during etching of the transition metal can be kept away from the vicinity of the transition metal surface or the vicinity of the wafer surface by the flow of the liquid. As a result, deposition or adhesion of an oxide to the transition metal surface is less likely to occur, and thus the flatness of the transition metal film is maintained.

The pH of the washing liquid is not particularly limited and can be, for example, the same as or different from the pH of the etching solution. In addition, an acid or an alkali can be used to control the pH, and a pH buffering agent can be included to suppress fluctuations in the pH. When the washing liquid contains an alkali, from the perspective of not containing a metal ion that causes problems in semiconductor manufacturing, the alkali is preferably an organic alkali, specifically an alkylammonium hydroxide, and is more preferably a tetraalkylammonium hydroxide. When the washing liquid contains an acid, an acid such as acetic acid, hydrochloric acid, sulfuric acid, nitric acid, formic acid, phosphoric acid, carbonic acid, or boric acid can be used.

### (Solvent)

The solvent used in the washing liquid is water or an organic solvent, and can be used singly or in combination of two or more types. Examples include, but are not limited to, water, alcohols, ethers, ketones, nitriles, amines, amides, carboxylic acids, and aldehydes. By using these solvents for washing, the transition metal oxide present on the transition metal surface or in the vicinity of the wafer surface can be washed away, and a transition metal surface on which adhesion or deposition of the transition metal oxide is suppressed and flatness is maintained can be obtained.

From the viewpoint of having a high ability to interact with the transition metal or the transition metal oxide, form a layer of solvent molecules on the surface of the transition metal or transition metal oxide, and to inhibit adsorption and deposition of the transition metal oxide, the solvent molecules are more preferably a solvent containing a heteroatom, that is, an oxygen atom, a nitrogen atom, a sulfur atom or a phosphorus atom, or a solvent containing a double bond or an aromatic ring. Examples of such solvents include, but of course are not limited to, methanol, ethanol, propanol, butanol, tetrahydrofuran, 1,4-dioxane, acetone, 4-methyl-2-pentanone, acetylacetone, acetonitrile, propionitrile, butyronitrile, isobutyronitrile, benzonitrile, ethylenediamine, pyridine, formamide, N-methylformamide, N,N-dimethylformamide, N-methylacetamide, N,N-dimethylacetamide, N-methylpropionamide, dimethyl sulfoxide, sulfolane, dimethylthioformamide, N-methylthiopyrrolidone, nitromethane, nitrobenzene, ethyl acetate, methyl acetate, formic acid, acetic acid, acetic acid, formic acid, lactic acid, glycolic acid, 2,2-bis (hydroxymethyl) propionic acid, gluconic acid, α-glucoheptonic acid, heptynoic acid, phenylacetic acid, phenylglycolic acid, benzilic acid, gallic acid, cinnamic acid, naphthoic acid, anisic acid, salicylic acid, cresotic acid, acrylic acid, benzoic acid, and other monocarboxylic acids, malic acid, adipic acid, succinic acid, maleic acid, tartaric acid, oxalic acid, glutaric acid, malonic acid, 1,3-adamantanedicarboxylic acid, diglycolic acid, and phthalic acid.

Further, from the viewpoint of having a high ability to dissolve a transition metal oxide, amongst the solvents containing an oxygen atom, a nitrogen atom, a sulfur atom, or a phosphorus atom and solvents containing a double bond or an aromatic ring, those solvents having an ability to coordinate to a transition metal or a transition metal oxide are more preferable. Examples of such solvents include, but of course are not limited to, piperidine, pyridine, pyridazine, pyrimidine, pyrazine, pyrrolidine, pyrroline, pyrrole, pyrazolidine, thiazole, oxazole, and thiazole, in addition to the above-mentioned solvents. The interaction between the solvent and the transition metal or transition metal oxide varies depending on the combination of the transition metal species/transition metal oxide species and the solvent, the temperature, the solute concentration and the like, but the solvent can be selected as appropriate in consideration of the etching conditions of the transition metal and the physical properties and solubility of the transition metal oxide produced by the etching.

### (Surfactant)

A solution containing a surfactant can also be used as the washing liquid. The surfactant is adsorbed to the surface of the transition metal or transition metal oxide, and thereby prevents the transition metal oxide from adhering to or depositing on the surface of the transition metal. As a result, deposition or adhesion of an oxide to the transition metal surface is less likely to occur, and thus the flatness of the transition metal film is maintained. The washing using a solution containing a surfactant can be carried out before the etching treatment, after the etching treatment, or before and after the etching. By washing the wafer containing the transition metal with the solution containing the surfactant before the etching treatment, wettability of the transition metal surface is improved, and the transition metal can be more uniformly etched. At this time, surface adsorption of the transition metal oxide during the etching is inhibited by the effect of the surfactant adsorbed to the transition metal surface, and the surface flatness after the etching is maintained. Further, by washing the wafer containing the transition metal with the solution containing the surfactant after the etching treatment, the surfactant is adsorbed by the transition metal oxide in the washing liquid present on the transition metal surface or in the vicinity of the wafer surface, and adhesion of the transition metal oxide to the surface of the transition metal is inhibited, and therefore the surface flatness after the etching is maintained.

As such a surfactant, any surfactant can be used as long as the surfactant is adsorbed to the transition metal to be etched or the transition metal oxide generated by the etching treatment, and the surfactant can be an ionic surfactant or a nonionic surfactant.

Among such surfactants, the surfactant is preferably an ionic surfactant from the viewpoint of exhibiting excellent solubility in a solvent and ease of concentration adjustment. Examples of such ionic surfactants include anionic surfactants such as carboxylic acid-based, sulfonic acid-based, sulfate-based and phosphate-based surfactants; cationic surfactants such as alkylamine-based and quaternary ammonium salt-based surfactants; and amphoteric surfactants such as carboxybetaine-based, imidazoline derivative-based, glycine-based and amine oxide-based surfactants.

Specific examples of amphoteric surfactants include carboxylic acid-based surfactants, such as aliphatic monocarboxylate salts, polyoxyethylene alkyl ether carboxylate salts, N-acylsarcosinate salts, N-acylglutamate salts and alpha-sulfofatty acid ester salts; sulfonic acid-based surfactants, such as dialkylsulfosuccinate salts, alkane sulfonate salts, alpha-olefin sulfonate salts, alkylbenzene sulfonate salts, naphthalene sulfonate salt-formaldehyde condensates, alkylnaphthalene sulfonate salts and N-methyl-N-acyltaurate salts; sulfate-based surfactants, such as alkylsulfate salts, polyoxyethylene alkyl ether sulfate salts and fat and oil sulfate salts; phosphate-based surfactants, such as alkyl phosphate salts, polyoxyethylene alkylether phosphate salts, and polyoxyethylene alkylphenyl ether phosphates; alkylamine salt-based surfactants, such as monoalkylamine salts, dialkylamine salts and trialkylamine salts; quaternary ammonium salt-based surfactants, such as alkyltrimethylammonium halides, dialkyldimethylammonium halides and alkylbenzalkonium halides; carboxybetaine-based surfactants, such as alkylbetaines and fatty acid amidoalkylbetaines; imidazoline derivative-based surfactants, such as 2-alkyl-N-carboxymethyl-N-hydroxyethylimidazolinium betaines; glycine-based surfactants, such as alkyldiethylene triaminoacetic acid and dialkyldiethylene triaminoacetic acid; and amine oxide-based surfactants, such as alkylamine oxides.

Furthermore, from the viewpoint of the surfactant being stably present in the washing liquid, being easily adsorbed to the transition metal or transition metal oxide, and effectively suppressing adhesion or deposition of the transition metal oxide, the surfactant contained in the washing liquid is more preferably a carboxybetaine-based surfactant, such as an alkylbetaine and a fatty acid amide alkylbetaine; an imidazoline derivative-based surfactant such as a 2-alkyl-N-carboxymethyl-N-hydroxyethylimidazolinium betaine, a glycine-based surfactant, such as alkyldiethylene triaminoacetic acid and dialkyldiethylene triaminoacetic acid; or an amine oxide-based surfactant such as an alkylamine oxide. The carbon number of the alkyl chain contained in these amphoteric surfactants is preferably from 1 to 25, more preferably from 3 to 20, and most preferably from 5 to 18.

As the solvent used in the surfactant-containing solution, water and the organic solvents listed in the description of the (Solvent) section above can be suitably used. The concentration of the surfactant in the surfactant-containing solution can be determined in consideration of the ease of adsorption to the transition metal and/or the transition metal oxide, the washing conditions, and the like. However, for example, the concentration is preferably from 0.1 ppm by mass to 10 mass %, and more preferably from 1 ppm by mass to 5 mass %. The pH of the surfactant-containing solution is not particularly limited, and can be, for example, the same as or different from the pH of the etching solution.

### (Ligand)

A solution containing a ligand can also be used as the washing liquid. The ligand coordinates to the surface of the transition metal or transition metal oxide, and thereby prevents the transition metal oxide from adhering to or depositing on the surface of the transition metal. As a result, deposition or adhesion of an oxide to the transition metal surface is less likely to occur, and thus the flatness of the transition metal film is maintained. The washing using a solution containing a ligand can be carried out before the etching treatment, after the etching treatment, or before and after the etching. By washing the wafer containing the transition metal with the solution containing the ligand before the etching treatment, a protective layer in which the ligands are coordinated to the surface of the transition metal is formed. The presence of the protective layer prevents the transition metal oxide present in the etching solution and generated by the etching of the transition metal from approaching the transition metal surface. As a result, adhesion or deposition of the transition metal oxide onto the transition metal surface is suppressed, and the flatness of the transition metal film is maintained. Further, by washing the wafer containing the transition metal with the solution containing the ligand before the etching treatment, the ligand is coordinated to the transition metal oxide, and an improvement in solubility of the transition metal oxide in the washing liquid can be expected. When the chemical species composed of the transition metal oxide and the ligand is stably present in the washing liquid, adhesion or deposition of the transition metal oxide to the transition metal surface is suppressed, and therefore the stability of the transition metal surface is maintained.

As such a ligand, any ligand can be used as long as the ligand is adsorbed to the transition metal to be etched or the transition metal oxide generated by the etching treatment. However, from the viewpoint of easily coordinating to the transition metal or transition metal oxide and forming a more stable complex, a ligand containing a heteroatom, that is, an oxygen atom, a nitrogen atom, a sulfur atom, or a phosphorus atom, is preferable. Examples of such ligands include, but are not limited to, ligands having an amino group, a phosphino group, a carboxyl group, a carbonyl group or a thiol group, and nitrogen-containing heterocyclic compounds.

Specific examples of such ligands preferably include amines, such as triethanolamine, nitrilotriacetic acid, ethylenediamine tetraacetic acid and glycine; thiols, such as cysteine and methionine; phosphines such as tributylphosphine and tetramethylene bis(diphenylphosphine); monocarboxylic acids and esters thereof, such as acetic acid, formic acid, lactic acid, glycolic acid, 2,2-bis (hydroxymethyl) propionic acid, gluconic acid, α-glucoheptonic acid, heptynoic acid, phenylacetic acid, phenylglycolic acid, benzilic acid, gallic acid, cinnamic acid, naphthoic acid, anisic acid, salicylic acid, cresotic acid, acrylic acid and benzoic acid; dicarboxylic acids and esters thereof, such as malic acid, adipic acid, succinic acid, maleic acid, tartaric acid, oxalic acid, dimethyl oxalate, glutaric acid, malonic acid, 1,3-adamantanedicarboxylic acid, diglycolic acid, and phthalic acid; tricarboxylic acids represented by citric acid, and esters thereof; tetracarboxylic acids represented by butane-1,2,3,4-tetracarboxylic acid, and esters thereof; hexacarboxylic acids represented by 1,2,3,4,5,6-cyclohexanehexacarboxylic acid, and esters thereof, and carbonyl compounds such as ethyl acetoacetate and dimethylmalonic acid.

More preferable examples thereof include monocarboxylic acids and esters thereof, such as acetic acid, formic acid, lactic acid, glycolic acid, 2,2-bis(hydroxymethyl) propionic acid, gluconic acid, α-glucoheptonic acid, heptynoic acid, phenylacetic acid, phenylglycolic acid, benzilic acid, gallic acid, cinnamic acid, naphthoic acid, anisic acid, salicylic acid, cresotic acid, acrylic acid and benzoic acid; dicarboxylic acids and esters thereof, such as malic acid, adipic acid, succinic acid, maleic acid, tartaric acid, oxalic acid, dimethyl oxalate, glutaric acid, malonic acid, 1,3-adamantanedicarboxylic acid, and diglycolic acid; tricarboxylic acids represented by citric acid, and esters thereof; tetracarboxylic acids represented by butane-1,2,3,4-tetracarboxylic acid, and esters thereof; hexacarboxylic acids represented by 1,2,3,4,5,6-cyclohexanehexacarboxylic acid, and esters thereof; and carbonyl compounds such as ethyl acetoacetate and dimethylmalonic acid.

Even more preferable examples include acetic acid, 2,2-bis(hydroxymethyl) propionic acid, succinic acid, oxalic acid, dimethyl oxalate, glutaric acid, malonic acid, 1,3-adamantanedicarboxylic acid, diglycolic acid, citric acid, butane-1,2,3,4-tetracarboxylic acid, 1,2,3,4,5,6-cyclohexanehexacarboxylic acid, and dimethylmalonic acid.

The nitrogen-containing heterocyclic compound refers to a compound having a heterocyclic ring containing one or more nitrogen atoms, and preferable examples include a piperidine compound, a pyridine compound, a piperazine compound, a pyridazine compound, a pyrimidine compound, a pyrazine compound, a 1,2,4-triazine compound, a 1,3,5-triazine compound, an oxazine compound, a thiazine compound, a cytosine compound, a thymine compound, a uracil compound, a pyrrolidine compound, a pyrroline compound, a pyrrole compound, a pyrazolidine compound, an imidazolidine compound, an imidazoline compound, a pyrazole compound, an imidazole compound, a triazole compound, a tetrazole compound, an oxazole compound, a thiazole compound, an oxadiazole compound, a thiadiazole compound, a thiazolidinedione compound, a succinimide compound, an oxazolidone compound, a hydantoin compound, an indoline compound, an indole compound, an indolizine compound, an indazole compound, an imidazole compound, an azaindazole compound, an indole compound, a purine compound, a benzisoxazole compound, a benzisothiazole compound, a benzoxazole compound, a benzothiazole compound, an adenine compound, a guanine compound, a carbazole compound, a quinoline compound, a quinolizine compound, a quinoxaline compound, a phthalazine compound, a quinazoline compound, a cinnoline compound, a naphthyridine compound, a pyrimidine compound, a pyrazine compound, a pteridine compound, an oxazine compound, a quinolinone compound, an acridine compound, a phenazine compound, a phenoxazine compound, a phenothiazine compound, a phenoxathiine compound, a quinuclidine compound, an azaadamantane compound, an azepine and a diazepine compound. More preferable examples include, but are not limited to, a pyridine compound, a piperazine compound, a triazole compound such as a benzotriazole compound, a pyrazole compound and an imidazole compound. When the nitrogen-containing heterocyclic compound has isomers, the isomers can be used as ligands for use in the present invention without distinction. For example, when the nitrogen-containing heterocyclic compound is an indole compound, the indole compound can be 1H-indole, 2H-indole, 3H-indole, or a mixture of these. Further, the nitrogen-containing heterocyclic compound can be modified with any functional group and have a structure in which a plurality of rings are condensed. The nitrogen-containing heterocyclic compound can be a single type, or a plurality of types can be combined and used. As the ligand used in the present invention, a nitrogen-containing heterocyclic compound and a ligand other than the nitrogen-containing heterocyclic compound can be used in combination.

When a lone pair of the heteroatom included in the ligand is coordinated to the transition metal or the transition metal oxide, formation of a protective layer on the surface of the transition metal and improvement in solubility of the transition metal oxide are achieved. In other words, the transition metal oxide generated during etching can be effectively removed by the effect of the ligand contained in the washing liquid. An example of such a transition metal is ruthenium, and an example of a transition metal oxide is ruthenium dioxide (RuO₂). When the above-described ligands have isomers, the present invention is not limited thereto. For example, lactic acid has a D-isomer and an L-isomer, but the ligand is not limited by the differences of such isomers.

As the solvent used in the ligand-containing solution, water and the organic solvents listed in the description of the (Solvent) section above can be suitably used. In addition, the concentration of the ligand in the ligand-containing solution can be determined in consideration of the ease of coordination to the metal and/or the metal oxide, the washing conditions, and the like. For example, the concentration is preferably from 0.1 mmol/L to 1 mol/L, and more preferably from 1 mmol/L to 0.5 mol/L. The pH of the surfactant-containing solution is not particularly limited, and can be, for example, the same as or different from the pH of the etching solution.

As desired, other additives typically used in processing liquids for manufacturing semiconductors can be included in the washing liquid used in the present invention, within a range that does not impair the object of the present invention. Examples of the additive that can be added include an acid, a metal anticorrosive, a water-soluble organic solvent, a fluorine compound, an oxidizing agent, a reducing agent, a complexing agent, a chelating agent, a surfactant, an antifoaming agent, a pH adjusting agent, and a stabilizing agent. The additive can be added alone, or a plurality of the additives can be added in combination.

### [Etching Method]

As the etching method used in the present invention, a known method for etching transition metals can be used as long as the object of the present invention is not impaired. For example, dry etching using a gas or wet etching using an etching solution can be used. However, wet etching, which has a high throughput and lower apparatus costs in comparison to dry etching, is preferable. Each etching method will be described below.

### (Dry Etching)

Dry etching is a method in which a material to be etched is etched with a reactive gas, ions, radicals, or the like. A known dry etching method can be used as the method of dry etching the transition metal. An example of a case in which a reactive gas is used is a method in which a high voltage is applied to a mixed gas of chlorine gas, oxygen gas and argon gas to form plasma, and a transition metal is etched using the chlorine/oxygen/argon plasma.

### (Wet Etching)

Wet etching is a method in which a material to be etched is brought into contact with an etching solution having a property of corroding and dissolving the material to be etched. A known etching solution for a transition metal can be used as an etching solution used for wet etching a transition metal. For example, wet etching can be performed using an etching solution containing an oxidizing agent and a solvent.

### (Etching Solution)

The etching solution used for wet etching is characterized by being capable of etching a transition metal while maintaining the flatness of the surface of the transition metal after etching. Therefore, the etching solution is suitably used in a step requiring etching of a transition metal in a semiconductor manufacturing process, and particularly in a step requiring flatness after etching.

### (Oxidizing Agent)

The oxidizing agent contained in the etching solution oxidizes the transition metal to convert the transition metal into a chemical species soluble in a solvent, and thereby wet etching of the transition metal can be carried out. Hereinafter, a case in which the transition metal is ruthenium will be described as an example. RuO₄, RuO₄⁻, or RuO₄²⁻ which are soluble in a solvent is produced by oxidation of the ruthenium by the oxidizing agent contained in the etching solution, and thereby the ruthenium is etched. Examples of the oxidizing agent include, but are not limited to, halogen oxyacid, halogen oxyacid ion, halogen oxyacid salt, permanganic acid, permanganate ion, permanganate salt, cerium (IV) salt, ferricyanide salt, hydrogen peroxide or ozone. Here, halogen oxyacid refers to hypochlorous acid, chlorous acid, chloric acid, perchloric acid, hypobromous acid, bromous acid, bromic acid, perbromic acid, hypoiodous acid, iodous acid, iodic acid, metaperiodic acid, or orthoperiodic acid. The halogen oxyacid ion refers to a hypochlorite ion, a chlorite ion, a chlorate ion, a perchlorate ion, a hypobromite ion, a bromite ion, a bromate ion, a perbromate ion, a hypoiodite ion, an iodite ion, an iodate ion, a metaperiodate ion or an orthoperiodate ion. Among the above-mentioned oxidizing agents, a halogen oxyacid or ion thereof and hydrogen peroxide can be stably used in a wide pH range and can be selected in a wide concentration range and thus are preferable as the oxidizing agent. Moreover, hypochlorous acid, hypobromous acid, permanganic acid, periodic acid (orthoperiodic acid and/or metaperiodic acid) or ions thereof are more preferable, hypochlorous acid, hypobromous acid, periodic acid (orthoperiodic acid and/or metaperiodic acid) or ions thereof are even more preferable, and hypobromous acid or hypobromite ion are most preferable.

The counter ion (cation) in the halogen oxyacid salt and the permanganate salt is an alkali metal ion, an alkaline earth metal ion, and an organic cation. However, if alkali metal ions and alkaline earth metal ions remain on a semiconductor wafer, the alkali metal ions and alkaline earth metal ions have an adverse effect on the semiconductor wafer (an adverse effect such as a decrease in the yield of the semiconductor wafer). Thus, the blending amount of such ions is preferably small, and in fact, such ions are preferably not contained. Therefore, the counter ion is preferably an organic cation, in consideration of industrial production, the organic cation is preferably at least one type of ammonium ion selected from the group consisting of a tetramethylammonium ion, a tetraethylammonium ion, a tetrapropylammonium ion and a tetrabutylammonium ion, and is particularly preferably a tetramethylammonium ion. Therefore, since sodium ions and calcium ions in the etching solution can be reduced by selecting tetramethylammonium ions as the counter ions, tetramethylammonium ions are preferably contained in the etching solution. The organic cation functions as an onium ion described below.

The concentration of the etching solution containing the oxidizing agent can be determined in consideration of the type of oxidizing agent, the film thickness of the transition metal, etching conditions (treatment temperature, treatment time, and pH), and the like, and is preferably 0.001 mol/L or greater and 2 mol/L or less, more preferably 0.01 mol/L or greater and 1.5 mol/L or less, and even more preferably 0.01 mol/L or greater and 1 mol/L or less. When the concentration is within this range, the transition metal can be suitably dissolved and washed.

### (Solvent Used in Etching Solution)

When wet etching, the solvent used in the etching solution is water or an organic solvent, and these solvents can be used alone, or two or more types can be mixed and used.

Also, the water is preferably a water from which metal ions, organic impurities, particles, or the like have been removed by a treatment such as distillation, ion exchange, filtration, or various types of adsorption, and pure water and ultrapure water are particularly preferable. Such water can be obtained by a known method widely used in semiconductor manufacturing.

For the organic solvent, any organic solvent that does not impair the function of the etching solution can be used. Examples include sulfolane, acetonitrile, carbon tetrachloride, and 1,4-dioxane, but of course, the organic solvent is not limited to these.

### (Additives)

An additive typically used in semiconductor processing liquids can be added, as desired, to the etching solution used in the present invention, within a range that does not impair the object of the present invention. Examples of the additives include acids, alkalis, metal corrosion inhibitors, fluorine compounds, oxidizing agents, reducing agents, chelating agents, anionic surfactants, cationic surfactants, nonionic surfactants, and antifoaming agents.

### (Treatment Temperature of Etching Solution)

The treatment temperature of the etching solution used in the present invention is preferably 10° C. or higher and 90° C. or lower, more preferably 40° C. and higher and 90° C. or lower, and even more preferably 40° C. or higher and 80° C. or lower. By setting the treatment temperature within the above range, the difference in the etching rates of one crystal plane to another crystal plane in the X-ray diffraction of the transition metal becomes small, and the etching amount ratio of the one crystal plane to the other crystal plane in the X-ray diffraction of the transition metal can be reduced.

### (Onium Ion)

The etching solution used in the present invention can further contain an onium ion. By containing the onium ion, the difference in the etching rates of one crystal plane to another crystal plane in the X-ray diffraction of the transition metal becomes small, and the etching amount ratio of the one crystal plane to the other crystal plane calculated from the X-ray diffraction of the metal can approach 1.

The onium ion is a quaternary onium ion, a tertiary onium ion, a secondary onium ion, and an onium ion substituted with hydrogen. Specifically, the onium ion is a cation, such as an ammonium ion, a phosphonium ion, a fluoronium ion, a chloronium ion, a bromonium ion, an iodonium ion, an oxonium ion, a sulfonium ion, a selenonium ion, a telluronium ion, an arsonium ion, a stibonium ion, and a bismuthonium ion, and an ammonium ion, a phosphonium ion, or a sulfonium ion is preferable. Further, the onium ion is more preferably an ammonium ion. The onium ion can be added to the etching solution in the form of an onium salt. The onium salt is composed of the onium ion and an anion.

The anion is a negatively charged ion and is not particularly limited, but is preferably a fluoride ion, chloride ion, bromide ion, iodide ion, hydroxide ion, nitrate ion, phosphate ion, sulfate ion, hydrogensulfate ion, methanesulfate ion, perchlorate ion, chlorate ion, chlorite ion, hypochlorite ion, perbromate ion, bromate ion, bromite ion, hypobromite ion, orthoperiodate ion, metaperiodate ion, iodate ion, iodite ion, hypoiodite ion, acetate ion, carbonate ion, hydrogen carbonate ion, fluoroborate ion, or trifluoroacetate ion, and is more preferably a hydroxide ion, a chloride ion or a bromide ion.

### (Ammonium Ion)

The ammonium ion is preferably a quaternary ammonium ion, which is stable in a liquid and is readily available from an industrial perspective. The quaternary ammonium ion is represented by the following formula (1).

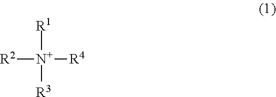

(In formula (1), R¹, R², R³ and R⁴ are each independently an alkyl group having a carbon number from 1 to 25, an ally group, an aralkyl group having an alkyl group with a carbon number from 1 to 25, or an aryl group. However, in a case in which R¹, R², R³, and R⁴ are alkyl groups, the number of carbons of at least one alkyl group among R¹, R², R³, and R⁴ is two or more. Also, in an aryl group of the aralkyl group and in a ring of the aryl group, at least one hydrogen can be substituted with fluorine, chlorine, an alkyl group having a carbon number from 1 to 10, an alkenyl group having a carbon number from 2 to 10, an alkoxy group having a carbon number from 1 to 9, or an alkenyloxy group having a carbon number from 2 to 9, and in these groups, at least one hydrogen can be substituted with fluorine or chlorine. Specific examples of quaternary ammonium ions that can be suitably used include an ethyltrimethyl ammonium ion, a tetraethyl ammonium ion, a tetrapropyl ammonium ion, a tetrabutyl ammonium ion, a tetrapentyl ammonium ion, a tetrahexyl ammonium ion, a triethylmethyl ammonium ion, a tributylmethyl ammonium ion, a tri-n-octylmethyl ammonium ion, a hexyltrimethyl ammonium ion, an n-octyhrimethyl ammonium ion, a nonyhrimethyl ammonium ion, a decyltrimethyl ammonium ion, a lauryltrimethyl ammonium ion, a tetradecyltrimethyl ammonium ion, a hexadecyltrimethyl ammonium ion, a heptadecyhrimethyl ammonium ion, an octadecyhrimethyl ammonium ion, a didecyldimethyl ammonium ion, a didodecyldimethyl ammonium ion, and a tetraheptyl ammonium ion.

### (Anionic Species)

The etching solution used in the present invention can further contain an anionic species for the purpose of suppressing a decrease in flatness after etching. Specifically, examples of the anionic species include halate ions, such as ClO₃⁻, BrO₃⁻, and IO₃⁻; halite ions, such as ClO₂⁻, BrO₂⁻, and IO₂⁻; and halide ions, such as Cl⁻, Br⁻ and I⁻. One of these anionic species can be contained in the etching solution, or two or more anionic species can be contained.

The concentration of one of the anionic species contained in the etching solution is preferably from 0.30 mol/L to 6.00 mol/L, more preferably from 0.30 mol/L to 3.00 mol/L, and most preferably from 0.30 mol/L to 1.00 mol/L. When the etching solution contains the anionic species within the range described above, an effect of maintaining a sufficient etching rate for the transition metal and suppressing a decrease in flatness due to etching is exhibited. When two or more types of the anionic species are contained in the etching solution, at least one type of the contained anionic species is preferably contained in the etching solution at an amount from 0.30 mol/L to 6.00 mol/L.

### (pH of Etching Solution)

The pH at 25° C. of the etching solution used in the present invention is preferably 8 or higher and 14 or lower.

The pH of the etching solution is preferably controlled within this range in order to adjust the etching amount ratio of one crystal plane of the transition metal to another crystal plane of the transition metal in the X-ray diffraction of the transition metal to within a range of 0.1 or greater and 10 or less.

To adjust the pH of the etching solution, an acid or an alkali can be added to the etching solution. The acid can be an inorganic acid or an organic acid, and examples include hydrofluoric acid, hydrochloric acid, hydrobromic acid, nitric acid, acetic acid, sulfuric acid, peroxodisulfuric acid, and formic acid, but in addition to these, a widely known acid used in an etching solution for semiconductors can be used without any limitation. As the alkali, an organic alkali is preferably used because such an alkali does not contain a metal ion that causes a decrease in yield in semiconductor manufacturing. Among the organic alkalis, a tetraalkyl ammonium hydroxide is preferable because it is readily available from an industrial perspective and easily and stably coexist with the oxidizing agent contained in the etching solution. Examples of such tetraalkylammonium hydroxides include tetramethyl ammonium hydroxide, ethyltrimethyl ammonium hydroxide, tetraethyl ammonium hydroxide, tetrapropyl ammonium hydroxide, tetrabutyl ammonium hydroxide, and choline. Among these, the organic alkali is more preferably tetramethyl ammonium hydroxide or ethyltrimethyl ammonium hydroxide because these organic alkalis provide a large number of hydroxide ions per unit weight and high-purity products thereof are readily available.

### (pH of Etching Solution Containing Hypochlorous Acid)

The pH of the etching solution containing hypochlorous acid at 25° C. is preferably 8 or higher and 14 or lower and more preferably 9 or higher and 13 or lower. It is preferable to control the pH of the etching solution within this range in order to adjust the etching amount ratio of one crystal plane of the transition metal to another crystal plane of the transition metal in the X-ray diffraction of the transition metal to within a range of 0.1 or greater and 10 or less.

### (pH of Etching Solution Containing Hypobromous Acid)

The pH of the etching solution containing hypobromous acid at 25° C. is preferably 8 or greater and 14 or less, more preferably 8 or greater and 13.5 or less, even more preferably 8 or greater and 13 or less, and particularly preferably 9 or greater and 12.5 or less. It is preferable to control the pH of the etching solution within this range in order to adjust the etching amount ratio of one crystal plane of the transition metal to another crystal plane of the transition metal in the X-ray diffraction of the transition metal to within a range of 0.1 or greater and 10 or less.

Another embodiment of the present invention is a method for producing a semiconductor containing a transition metal, the production method including the above-described method for processing a semiconductor containing a transition metal.

For example, the production method of the present embodiment can include, in addition to the processing method described above, a known step used in a method for producing a semiconductor, such as one or more steps selected from a wafer manufacturing step, an oxide film formation step, a transistor formation step, a wiring formation step, and a CMP step.

### (Processing Liquid)

Yet another embodiment of the present invention is a processing liquid for semiconductors, the processing liquid containing an amphoteric surfactant or an amine. Here, the amphoteric surfactant is a carboxybetaine-based, an imidazoline derivative-based, a glycine-based, or an amine oxide-based amphoteric surfactant. More specific examples thereof include carboxybetaine-based surfactants such as alkyl betaine and fatty acid amide alkyl betaine; imidazoline derivative-based surfactants such as 2-alkyl-N-carboxymethyl-N-hydroxyethylimidazolinium betaine; glycine-based surfactants such as alkyldiethylene triaminoacetic acid and dialkyldiethylene triaminoacetic acid; and amine oxide-based surfactants such as alkylamine oxides.

Furthermore, the amine can be any of a tertiary amine, a secondary amine, or a primary amine, and examples include aliphatic amines, such as trimethylamine, dimethylamine, monomethylamine, triethylamine, diethylmethylamine, ethyldimethylamine, tripropylamine, tributylamine, ethylenediamine, triethanolamine, N,N-diisopropylethylamine, tetramethylethylenediamine, and hexamethylenediamine; aromatic amines, such as aniline and catecholamine; heterocyclic amines such as pyrrolidine, piperidine, piperazine, morpholine, quinuclidine, pyrrole, pyrazole, imidazole, pyridine, pyridazine, pyrimidine, pyrazine, oxazole, and thiazole; and amine derivatives, such as ether amines and amino acids. In addition, among the compounds listed in the (Ligand) section described above, the chemical species containing a nitrogen atom can also be suitably used as the amine contained in the processing liquid of the present embodiment, but the amine is, of course, not limited thereto. Furthermore, in these amines, the hydrogen or carbon atom bonded to the nitrogen can be substituted with another atom or functional group.

When the processing liquid of the present embodiment contains the amphoteric surfactant or the amine, the effect of suppressing the adhesion or deposition of the transition metal oxide to the transition metal surface is exhibited by the mechanism presented in the description of the surfactant or ligand contained in the washing liquid described above. As a result, the surface of the transition metal treated with the processing liquid of the present embodiment is not easily affected by the transition metal oxide, and a decrease in the flatness of the transition metal surface accompanying the chemical solution treatment can be suppressed. Therefore, in the manufacturing of a semiconductor element, the processing liquid of the present embodiment can be suitably used in a step in which flatness of the transition metal is required. Examples of such steps include a transistor formation step, a wiring formation step, and a CMP step, but of course the processing liquid can be used without being limited to these steps. The processing liquid of the present embodiment can be used alone or in combination with another processing liquid. For example, by applying the processing liquid of the present embodiment to the wafer or immersing the wafer in the processing liquid of the present embodiment, the amphoteric surfactant or the amine can be coordinated to the transition metal surface contained in the wafer. At this time, the amphoteric surfactant or amine coordinated to the transition metal surface functions as a protective layer for the transition metal, and at the same time, plays a role in preventing the transition metal oxide, an organic matter, or other precipitate from being deposited on the transition metal surface. As a result, the flatness of the transition metal surface after the chemical solution treatment can be maintained. Accordingly, the processing liquid of the present embodiment is preferably used before the transition metal contained in the wafer is processed using another processing liquid. However, as described below, when the processing liquid of the present embodiment contains an oxidizing agent or the like, the processing liquid can simultaneously protect the transition metal through the amphoteric surfactant or amine and process the transition metal through the oxidizing agent or the like.

Further, as described in the description of the etching solution above, when a wet treatment is to be carried out a plurality of times using the processing liquid containing the oxidizing agent, the processing liquid of the present embodiment can be suitably used before and/or after the treatment by the oxidizing agent. By processing the wafer containing the transition metal with the processing liquid of the present embodiment every time the oxidizing agent is used, the amount of the amphoteric surfactant or amine coordinated to the surface of the transition metal can be controlled, and a plurality of treatments with the oxidizing agent can be implemented in the same manner. Accordingly, even when the wet treatment with the oxidizing agent has been carried out a plurality of times, the effect of the oxidizing agent is not changed, and thus the effect of the chemical solution treatment can be controlled by the number of times of the wet treatment. For example, when the wet treatment is etching using an oxidizing agent, the amount of etching after a plurality of treatments can be controlled by the product of the amount of etching by one etching treatment and the number of treatments, and thereby precise processing can be carried out. Further, since the flatness of the transition metal surface is maintained by using the processing liquid of the present embodiment, even when the wet treatment has been carried out a plurality of times, a subsequent treatment is not hindered by the roughness of the transition metal surface or the like.

The above-mentioned ranges and conditions presented in the description of the surfactant or ligand contained in the washing liquid can be suitably used for the concentration of the amphoteric surfactant or amine contained in the processing liquid, the pH of the processing liquid, the solvent of the processing liquid, and other additives that can be contained in the processing liquid.

The processing liquid according to the present embodiment can further contain an oxidizing agent. When an oxidizing agent is contained in the processing liquid, the oxidation-reduction potential (ORP) of the processing liquid is stabilized, and the chemical state (oxidation state) of the transition metal oxide is also stabilized. As a result, the oxidation state of the transition metal oxide is lowered, and adhesion or deposition on the transition metal surface is less likely to occur. Thus, a transition metal surface having excellent flatness and for which the effect of the transition metal oxide is minimal can be obtained. Further, as described above, since protection of the transition metal surface by the amphoteric surfactant or the amine and the etching of the transition metal can be carried out at the same time, transition metal processing with excellent flatness and high production efficiency can be achieved.

As such an oxidizing agent, an oxidizing agent given as an example in the description of the (Oxidizing Agent) section above can be suitably used, and examples thereof include halogen oxyacid, halogen oxyacid ion, halogen oxyacid salt, permanganic acid, permanganate ion, permanganate salt, cerium (IV) salt, ferricyanide salt, hydrogen peroxide or ozone. Among these, a halogen oxyacid or ion thereof and hydrogen peroxide are preferable as the oxidizing agent because they can be stably used in a wide pH range and can be selected in a wide concentration range. Moreover, hypochlorous acid, hypobromous acid, permanganic acid, periodic acid (orthoperiodic acid and/or metaperiodic acid) or ions thereof are more preferable, hypochlorous acid, hypobromous acid, periodic acid (orthoperiodic acid and/or metaperiodic acid) or ions thereof are even more preferable, and hypobromous acid or hypobromite ions are most preferable.

In a case in which hypobromous acid or a hypobromite ion are contained in the processing liquid of the present embodiment, the details described in the (Etching Solution) section above with regard to the oxidizing agent contained in the etching solution can be suitably adopted for the concentration of the hypobromous acid or a hypobromite ion, the pH of the processing liquid, and the like. When the oxidizing power of the oxidizing agent contained in the processing liquid is strong, the amphoteric surfactant or the amine may be decomposed. In such a case, the influence of the oxidizing agent can be reduced by appropriately adjusting the type and amount of the oxidizing agent, the pH of the processing liquid, and the order in which the oxidizing agent, or the amphoteric surfactant or amine is added to the processing liquid. Further, a decomposition product of the amphoteric surfactant or amine can be produced in the processing liquid by utilizing the decomposition of the amphoteric surfactant or amine by the oxidizing agent. For example, a processing liquid containing a secondary amine and/or a primary amine can be produced by reacting a tertiary amine with the oxidizing agent, and the resulting processing liquid can also be used.

Furthermore, the processing liquid of the present embodiment can contain the above-described surfactant, ligand, onium ion, ammonium ion, anionic species, and other additives, and as the conditions in the case of using these additives, the details described in the description of the additives can be suitably adopted without any limitation.

The solvent of the processing liquid of the present embodiment is not particularly limited, and can be water or an organic solvent. If the solubility of the amphoteric surfactant or amine contained in the processing liquid is poor, the amphoteric surfactant or amine could be deposited as particles on the surface of the wafer containing the transition metal. In semiconductor manufacturing, particles cause a decrease in yield and thus are not preferable. Also, from the perspective of increasing the solubility of the amphoteric surfactant or amine and reducing the potential of deposition of particles on the transition metal surface, the solvent used in the processing liquid of the present embodiment is preferably water, the water is preferably a water from which metal ions, organic impurities, particles, or the like have been removed by distillation, ion exchange, filtration, various types of adsorption or the like, and pure water and ultrapure water are particularly preferable. Water contained in the processing liquid according to the present embodiment is preferably water from which metal ions, organic impurities, particles, or the like have been removed by distillation, ion exchange, filtration, various types of adsorption, or the like, and pure water or ultrapure water is particularly preferable. Such water can be obtained by a known method widely used in semiconductor manufacturing. As the solvent, water and an organic solvent can be used in combination. When water and an organic solvent are used in combination, oxidation of the transition metal proceeds in a relatively moderate manner, and thus oxidation of wiring or the like of a circuit forming portion can be suppressed. When water and an organic solvent are used in combination, the mass ratio of the water to the organic solvent (water/organic solvent) can be approximately from 60/40 to 99.9/0.1.

### (Production Method)

The method for producing the processing liquid of the present embodiment is not particularly limited, and for example, the processing liquid can be produced by dissolving an amphoteric surfactant or amine in the solvent described above. When there is a concern that particles could be generated in the processing liquid due to the dissolution or dispersion of the amphoteric surfactant or amine, after the amphoteric surfactant or amine has been added to the solvent, the solution or dispersion can be stirred, heated and circulated to promote the dissolution of the amphoteric surfactant or amine, or the particles can be removed by filtration using an appropriate filter.

### (Use of Processing Liquid)

The processing liquid of the present embodiment contains an amphoteric surfactant or amine, and the amphoteric surfactant or amine coordinates to the transition metal surface and thereby forms a protective layer, and thus the processing liquid can suppress surface roughness when etching the transition metal, and can maintain flatness of the transition metal surface even after etching. The transition metal to which the processing liquid of the present embodiment can be suitably applied is not particularly limited, and for example, Ru, Rh, Ti, Ta, Co, Cr, Hf, Os, Pt, Ni, Mn, Cu, Zr, La, Mo, W and the like can be suitably treated. Among these, Ru, W. Mo, and Cr are easily coordinated by the above-described amphoteric surfactant or amine and are effectively protected, and therefore the flatness of the surface can be suitably maintained even after the etching treatment. Therefore, the processing liquid of the present embodiment can etch ruthenium, tungsten, molybdenum, and chromium contained in the wafer while maintaining the flatness thereof.

### EXAMPLES

The present invention will be described more specifically below by examples, but the present invention is not limited to these examples.

### (Film Formation of Transition Metal and Amount of Change in Film Thickness)

Transition metal films used in the examples and comparative examples were formed as follows. An oxide film was formed on a silicon wafer using a batch-type thermal oxidation furnace, and a transition metal film was formed on the oxide film using a sputtering method. When the transition metal was ruthenium, a film of ruthenium was formed with a thickness of 1200 Å (±10%). When the transition metal was molybdenum, a film of molybdenum was formed with a thickness of 1000 Å (±10%). The sheet resistance was measured with a four-probe resistance measuring device (Loresta-GP, manufactured by Mitsubishi Chemical Analytech Co., Ltd.) and converted to a film thickness, and this was used as the film thickness of the transition metal before etching treatment. The sheet resistance was also similarly measured with the four-probe resistance measuring device after the etching treatment and converted to a film thickness, and this was used as the film thickness of the transition metal after the etching treatment. The difference between the film thickness of the transition metal after the etching treatment and the film thickness of the transition metal before the etching treatment was used as an amount of change in the film thickness before and after the etching treatment.

### (Calculation Method of Etching Rate of Transition Metal)

For each example and comparative example, 60 ml, of a produced etching solution was prepared in a fluororesin container with a lid (94.0 mL PFA container, manufactured by As One Corporation). Each sample piece prepared to a size of 10×20 mm was immersed in the etching solution at a temperature from 10 to 90° C. until the transition metal film was etched by 30 nm. A value obtained by dividing the amount of change in the film thickness before and after the etching treatment by the immersion time was calculated as the etching rate and evaluated as the etching rate of the present invention.

(Preparation of Mixed Solution of Tetramethylammonium Hypochlorite ((CH₃)₄NClO) and Tetramethylammonium Hydroxide)

In a 2-L glass three-neck flask (manufactured by Cosmos Bead Co., Ltd.), 209 g of a 25 mass % tetramethylammonium hydroxide aqueous solution and 791 g of ion-exchanged water were mixed, and a 5.2 mass % tetramethylammonium hydroxide aqueous solution was obtained. The pH at this time was 13.8.

Next, a rotor (manufactured by As One Corporation, full length 30 mm×diameter 8 mm) was inserted into the three-neck flask. A thermometer protecting tube (manufactured by Cosmos Bead Co., Ltd., bottom-sealed type) and a thermometer were inserted into one opening, the leading end of a PFA tube (F-8011-02, manufactured by Flon Industry) connected to a chlorine gas cylinder and a nitrogen gas cylinder in a state enabling optional switching between chlorine gas and nitrogen gas was inserted into another opening and immersed in the bottom of the solution. The remaining opening was connected to a gas-washing bottle (gas-washing bottle, Model No. 2450/500, manufactured by As One Corporation) filled with a 5 mass % sodium hydroxide aqueous solution. Nitrogen gas was then introduced through the PFA tube at 200 ccm (25° C.) for 20 minutes, and carbon dioxide in the gas phase section was purged.

Subsequently, a magnetic stirrer (C-MAG HS10, manufactured by As One Corporation) was placed in the bottom portion of the three-neck flask, and while the magnetic stirrer was rotated at 300 rpm and the periphery of the three-neck flask was cooled with iced water, chlorine gas (manufactured by Fujiox Co., Ltd., specification purity of 99.4%) was supplied at 200 ccm (25° C.) for 180 minutes, and a mixed solution of 0.28 mol/L tetramethylammonium hypochlorite and 0.01 mol/L tetramethylammonium hydroxide was obtained. At this time, the solution temperature during the reaction was 11° C.

### (Measurement Method of Hypochlorite Ion and Hypobromite Ion Concentrations)

The hypochlorite ion and hypobromite ion concentrations were measured using an ultraviolet-visible spectrophotometer (UV-2600, manufactured by Shimadzu Corporation). A calibration curve was created using an aqueous solution of hypobromite ions and hypochlorite ions with known concentrations, and the hypochlorite ion concentration and hypobromite ion concentration in the produced etching solution were determined.

### (Calculation Method of Etching Amount Ratio of Ruthenium (002) to any One of Crystal Planes of Ruthenium Excluding Ruthenium (002))

Using an X-ray diffractometer (D2 PHASER, manufactured by Bruker Corporation), the peak areas of ruthenium (002) of the ruthenium film and any one of the crystal planes of ruthenium excluding ruthenium (002) before and after the etching treatment were determined. The measurement conditions were as follows.
X-ray source: Cu/Kα ray
Tube voltage/current: 30 kV/10 mA
Scanning speed: 11 deg/min
Scanning range: 10 to 90°

A value obtained by subtracting the peak area of ruthenium (002) after the etching treatment from the peak area of ruthenium (002) before the etching treatment was defined as the amount of change in the peak area of ruthenium (002). The amount of change in the peak area of ruthenium (002) was divided by the peak area of ruthenium (002) before the etching treatment to obtain a percentage value, and the obtained percentage value was used as the change rate of ruthenium (002). The change rate of any one of the crystal planes of ruthenium excluding ruthenium (002) was also calculated in the same manner as the change rate of ruthenium (002).

Next, a value obtained by dividing the change rate of the peak area of ruthenium (002) by the change rate of the peak area of any one of the crystal planes of ruthenium excluding ruthenium (002) was defined as the etching amount ratio of ruthenium (002) to any one of the crystal planes of ruthenium excluding ruthenium (002). The etching amount ratio and the etching rate ratio are equal to each other, and as the etching rate ratio approaches 1, the etching rate difference is reduced, and as a result, a decrease in flatness is suppressed.

### (Calculation Method of Etching Rate of any One of Crystal Planes of Ruthenium Excluding Ruthenium (002))

A case in which the any one of the crystal planes of ruthenium excluding ruthenium (002) is the crystal plane (101) will be described below. The peak areas of ruthenium (101) before and after the etching treatment were determined using an X-ray diffractometer (D2 PHASER, manufactured by Bruker Corporation). The change rate of ruthenium (101) was calculated by the same method as the change rate of ruthenium (002). A value obtained by multiplying the film thickness before the etching treatment by the change rate of ruthenium (101) was defined as the amount of change in film thickness of ruthenium (101), and a value obtained by dividing this amount of change in film thickness of ruthenium (101) by the immersion time was defined as the etching rate of ruthenium (101).

### (Calculation Method of Etching Amount Ratio of Molybdenum (110) to any One of Crystal Planes of Molybdenum Excluding Molybdenum (l 10))

Using an X-ray diffractometer (D2 PHASER, manufactured by Bruker Corporation), the peak areas of molybdenum (110) of the molybdenum film and any one of the crystal planes of molybdenum excluding molybdenum (110) before and after the etching treatment were determined. The measurement conditions were the same as in the case of ruthenium.

A value obtained by subtracting the peak area of molybdenum (110) after the etching treatment from the peak area of molybdenum (110) before the etching treatment was defined as the amount of change in the peak area of molybdenum (110). The amount of change in the peak area of molybdenum (110) was divided by the peak area of molybdenum (110) before the etching treatment to obtain a percentage value, and the obtained percentage value was used as the change rate of molybdenum (110). The change rate of any one of the crystal planes of molybdenum excluding molybdenum (110) was also calculated by the same method as the change rate of molybdenum (110).

Next, a value obtained by dividing the change rate of the peak area of molybdenum (110) by the change rate of the peak area of any one of the crystal planes of molybdenum excluding molybdenum (110) was defined as the etching amount ratio of molybdenum (110) to any one of the crystal planes of molybdenum excluding molybdenum (110). The etching amount ratio and the etching rate ratio are equal to each other, and as the etching rate ratio approaches 1, the etching rate difference is reduced, and as a result, a decrease in flatness is suppressed.

### (Calculation Method of Etching Rate of any One of Crystal Planes of Molybdenum Excluding Molybdenum (110))

A case in which the any one of the crystal planes of molybdenum excluding molybdenum (110) is the crystal plane (211) will be described below. The peak areas of molybdenum (211) before and after the etching treatment were determined using an X-ray diffractometer (D2 PHASER, manufactured by Bruker Corporation). The change rate of molybdenum (211) was calculated by the same method as the change rate of molybdenum (110). A value obtained by multiplying the film thickness before the etching treatment by the change rate of molybdenum (211) was defined as the amount of change in film thickness of molybdenum (211), and a value obtained by dividing this amount of change in film thickness of molybdenum (211) by the immersion time was defined as the etching rate of molybdenum (211).

(Surface Evaluation after Etching)

The transition metal surface before and after etching was observed with a field emission scanning electron microscope (JSM-7800F Prime, manufactured by JEOL Ltd.), flatness of the surface was confirmed, and the surface was evaluated by the following criteria. The surface roughness was evaluated as A to D in order from the smallest roughness, and evaluations of A to C were all considered to be acceptable and an evaluation of D was considered to be unacceptable.
A: A decrease in flatness (presence of surface roughness) was not observed.
B: A decrease in flatness (presence of surface roughness) was slightly observed.
C: A decrease in flatness (presence of surface roughness) was observed over the entire surface, but the decrease in flatness (presence of surface roughness) was not significant.
D: A decrease in flatness (presence of surface roughness) was observed over the entire surface, and the decrease in flatness (presence of surface roughness) was significant.

### (pH Measurement)

The pH of 10 mL of the measurement sample liquid prepared in each example and comparative example was measured using a tabletop pH meter (LAQUA F-73, manufactured by Horiba, Ltd.). The pH was measured after the etching solution was prepared and stabilized at 25° C.

### (Reagent)

The reagents used in the examples and comparative examples were as follows.
Sodium hypochlorite pentahydrate (NaClO·5H₂O): manufactured by Fujifilm Wako Pure Chemical Corporation
Orthoperiodic acid (H₅IO₆): manufactured by Fujifilm Wako Pure Chemical Corporation
Sodium bromide (NaBr): manufactured by Fujifilm Wako Pure Chemical Corporation
Tetramethylammonium bromide ((CH₃)₄NBr): manufactured by Tokyo Chemical Industry Co., Ltd.
15 wt % HCl: manufactured by Kanto Chemical Co., Inc. (prepared by diluting 35 wt % HCl with ultrapure water)
1 mol/L NaOH: manufactured by Fujifilm Wako Pure Chemical Corporation
25 wt % tetramethylammonium hydroxide ((CH₃)₄NOH): manufactured by Tokyo Chemical Industry Co., Ltd.
Tetramethylammonium chloride (C₄H₁₂ClN): manufactured by Tokyo Chemical Industry Co., Ltd.
Tetrapropylammonium chloride (C₁₂H₂₈ClN): manufactured by Tokyo Chemical Industry Co., Ltd.
Octyltrimethylammonium chloride (C₁₁H₂₆ClN): manufactured by Tokyo Chemical Industry Co., Ltd.
Octadecyltrimethylammonium chloride (C₂₁H₄₆ClN): manufactured by Tokyo Chemical Industry Co., Ltd.
Didodecyldimethylammonium chloride (C₂₆H₅₆ClN): manufactured by Tokyo Chemical Industry Co., Ltd.

### Example 1

### (Production of Etching Solution)

A 1 mol/L NaOH aqueous solution and ultrapure water were added to sodium hypochlorite pentahydrate to prepare an aqueous solution having a pH of 13.0 and containing 1.0 mol/L of hypochlorite ions. A 1 mol/L NaOH aqueous solution and ultrapure water were added to sodium bromide to prepare an aqueous solution having a pH of 13.0 and containing 1.0 mol/L of bromide ions. The aqueous solution containing hypochlorite ions and the aqueous solution containing bromide ions were mixed at a volume ratio of 1:1 to thereby prepare an etching solution containing hypobromite ions and described as Example 1 in Table 1.

### (Preparation of Sample to be Etched)

A ruthenium film and a molybdenum film were formed by the method described in the section of (Film formation of transition metal and amount of change in film thickness), the films were cut to sample pieces having a size of 10×20 mm, and these sample pieces were used for evaluation.

### (Evaluations)

Ruthenium was treated in accordance with the method described above using the produced etching solution, after which the etching amount ratio of ruthenium (002) to ruthenium (101) or ruthenium (100) and the surface flatness were evaluated.

In addition, molybdenum was treated in accordance with the method described above using the produced etching solution, after which the etching amount ratio of molybdenum (110) to molybdenum (211) and the surface flatness were evaluated.

### Example 2

In Example 2, an etching solution was prepared in the same manner as in Example 1 with the exception that the pH of the hypochlorite ion-containing aqueous solution and the pH of the bromide ion-containing aqueous solution were set to 12.5, and the concentrations were set to 0.2 mol/L such that the etching solution had the composition shown in Table 1, and evaluations were conducted using a ruthenium film and a molybdenum film (sample pieces) prepared in the same manner as in Example 1.

### Example 3

In Example 3, 15 wt % of HCl and ultrapure water were added to a mixed solution of a 0.28 mol/L tetramethylammonium hypochlorite aqueous solution and 0.01 mol/L tetramethylammonium hydroxide, the mixed solution being obtained by the method described in the section of (Preparation of mixed solution of tetramethylammonium hypochlorite ((CH₃)₄NClO) and tetramethylammonium hydroxide) above, and thereby an aqueous solution (hereinafter, referred to as the aqueous solution A) having a pH of 9.0 and containing 0.012 mol/L of hypochlorite ions and tetramethylammonium ions was prepared. Also, a 25% tetramethylammonium hydroxide aqueous solution and ultrapure water were added to tetramethylammonium bromide to prepare an aqueous solution (hereinafter, referred to as the aqueous solution B) having a pH of 9.0 and containing 0.012 mol/L of bromide ions and tetramethylammonium ions. The aqueous solution A and the aqueous solution B were mixed at a volume ratio of 1:1 to prepare an etching solution described as Example 3 in Table 1. Evaluations were conducted using a ruthenium film and a molybdenum film (sample pieces) prepared in the same manner as in Example 1.

### Examples 4 to 8

In Example 4, an etching solution was prepared in the same manner as in Example 3 with the exception that the pH values of the aqueous solutions A and B were set to 8.0, and the hypochlorite ion concentration of the aqueous solution A and the bromide ion concentration of the aqueous solution B were set to 0.02 mol/L, such that the etching solution had the composition shown in Table 1, and evaluations were conducted using a ruthenium film (sample piece) prepared in the same manner as in Example 1. In Examples 5 to 8 also, etching solutions were prepared in the same manner as in Example 3 with the exception that the pH and concentrations of the aqueous solutions A and B were changed such that the etching solutions had the composition shown in Table 1, and evaluations were carried out using a ruthenium film and a molybdenum film (sample pieces) prepared in the same manner as in Example 1.

### Examples 9 and 10

In each of Examples 9 and 10, an etching solution was prepared by adding a 25 wt % tetramethylammonium hydroxide aqueous solution and ultrapure water to orthoperiodic acid such that the etching solution had the composition shown in Table 1, and evaluations were carried out using a ruthenium film and a molybdenum film (sample pieces) prepared in the same manner as in Example 1.

### Example 11

In Example 11, an aqueous solution (hereinafter, referred to as the aqueous solution A1) having a pH of 11.0 and containing 0.012 mol/L of hypochlorite ions and tetramethylammonium ions was prepared using the same method as in Example 3. Tetrapropylammonium chloride was added to tetramethylammonium bromide to have a concentration of tetrapropylammonium chloride of 0.006 mol/L, and ultrapure water and a 25 wt % tetramethylammonium hydroxide aqueous solution were added to prepare an aqueous solution (hereinafter, referred to as the aqueous solution B1) having a pH of 11.0 and containing 0.006 mol/L of tetrapropylammonium chloride, 0.012 mol/L of bromide ions, and tetramethylammonium ions. The aqueous solutions A1 and B1 were mixed at a volume ratio of 1:1 to prepare an etching solution containing hypobromite ions and 0.003 mol/L of tetrapropylammonium ions as described in Table 1. Evaluations were conducted using a ruthenium film and a molybdenum film (sample pieces) prepared in the same manner as in Example 1.

### Example 12

In Example 12, an aqueous solution (hereinafter, referred to as the aqueous solution A2) having a pH of 12.5 and containing 1.0 mol/L of hypochlorite ions was prepared using the same method as in Example 1. Octyltrimethylammonium chloride was added to sodium bromide to have a concentration of octyltrimethylammonium chloride of 0.004 mol/L, and ultrapure water and a 1 mol/L NaOH aqueous solution were added thereto to prepare an aqueous solution (hereinafter, referred to as the aqueous solution B2) having a pH of 12.5 and containing 0.004 mol/L of octyltrimethylammonium chloride and 1.0 mol/L of bromide ions. The aqueous solutions A2 and B2 were mixed at a volume ratio of 1:1 to prepare an etching solution containing hypobromite ions and 0.002 mol/L of octyhrimethylammonium ions as described in Table 1. Evaluations were conducted using a ruthenium film and a molybdenum film (sample pieces) prepared in the same manner as in Example 1.

### Example 13

In Example 13, an aqueous solution (hereinafter, referred to as the aqueous solution A3) having a pH of 10.0 and containing 0.02 mol/L of hypochlorite ions and tetramethylammonium ions was prepared using the same method as in Example 3. Octadecyltrimethylammonium chloride was added to tetramethylammonium bromide to have a concentration of octadecyhrimethylammonium chloride of 0.002 mol/L, and ultrapure water and a 25 wt % tetramethylammonium hydroxide aqueous solution were added thereto to prepare an aqueous solution (hereinafter, referred to as the aqueous solution B3) having a pH of 10.0 and containing 0.002 mol/L of octadecyltrimethylammonium chloride, 0.02 mol/L of bromide ions, and tetramethylammonium ions. The aqueous solutions A3 and B3 were mixed at a volume ratio of 1:1 to prepare an etching solution containing hypobromite ions and 0.001 mol/L of octadecyltrimethylammonium ions as described in Table 1. Evaluations were conducted using a ruthenium film and a molybdenum film (sample pieces) prepared in the same manner as in Example 1.

### Example 14

In Example 14, an etching solution was prepared in the same manner as in Example 13 with the exception that the pH of the aqueous solution A3 was set to 11.0, the hypochlorite ion concentration was set to 0.06 mol/L, the pH of the aqueous solution B3 was set to 11.0, 0.004 mol/L of octyltrimethylammonium chloride was used in place of octadecyltrimethylammonium chloride, and the bromide ion concentration was set to 0.06 mol/L such that the etching solution had the pH and composition shown in Table 1, and evaluations were conducted using a ruthenium film and a molybdenum film (sample pieces) prepared in the same manner as in Example 1.

### Example 15

In Example 15, an etching solution containing hypobromite ions was prepared in the same manner as in Example 12 with the exception that the pH values of the aqueous solutions A2 and B2 were set to 13.5, and the hypochlorite ion concentration of the aqueous solution A2 and the bromide ion concentration of the aqueous solution B2 were set to 2.0 mol/L such that the etching solution had the pH and composition shown in Table 1, and evaluations were conducted using a ruthenium film and a molybdenum film (sample pieces) prepared in the same manner as in Example 1. At this time, the onium ion concentration was adjusted such that the concentration of octyltrimethylammonium ions was 0.002 mol/L.

### Example 16

In Example 16, 15 wt % of HCl and ultrapure water were added to the mixed solution of the tetramethylammonium hypochlorite aqueous solution and tetramethylammonium hydroxide obtained by the above operation described above, and an etching solution containing hypochlorite ions as described in Table 1 was thereby prepared. At this time, tetramethylammonium chloride was added such that the chloride ion concentration in the etching solution was 0.5 mol/L. Evaluations were conducted using a ruthenium film and a molybdenum film (sample pieces) prepared in the same manner as in Example 1.

### Example 17

In Example 17, an etching solution was prepared in the same manner as in Example 1 with the exception that 20% ethyltrimethylammonium hydroxide was used as an alkali for adjusting the pH, and evaluations were carried out using a ruthenium film and a molybdenum film (sample pieces) prepared in the same manner as in Example 1.

### Example 18

In Example 18, 25% tetramethylammonium hydroxide and ultrapure water were added to a mixed solution of a 0.28 mol/L tetramethylammonium hypochlorite aqueous solution and 0.01 mol/L tetramethylammonium hydroxide, the mixed solution being obtained in the section of (Preparation of mixed solution of tetramethylammonium hypochlorite ((CH₃)₄NClO) and tetramethylammonium hydroxide) above, and an aqueous solution (hereinafter, referred to as the aqueous solution A4) having a pH of 13.0 and containing 0.2 mol/L of hypochlorite ions and tetramethylammonium ions was prepared. Also, ethyltrimethylammonium hydroxide, a 25% tetramethylammonium hydroxide aqueous solution, and ultrapure water were added to tetramethylammonium bromide to prepare an aqueous solution (hereinafter, referred to as the aqueous solution B4) having a pH of 13.0 and containing 0.2 mol/L of bromide ions and tetramethylammonium ions. The aqueous solutions A4 and B4 were mixed at a volume ratio of 1:1 to prepare an etching solution described as Example 17 in Table 1. Evaluations were conducted using a ruthenium film and a molybdenum film (sample pieces) prepared in the same manner as in Example 1.

### Example 19

In Example 19, an aqueous solution (hereinafter, referred to as the aqueous solution A5) having a pH of 10.0 and containing 0.2 mol/L of hypochlorite ions and tetramethylammonium ions was prepared using the same method as in Example 16. Further, a 0.2 mol/L orthoperiodic acid aqueous solution (hereinafter, referred to as the aqueous solution B5) having a pH of 10.0 was prepared in the same manner as in Example 9. The aqueous solution A5 and the aqueous solution B5 were mixed at a volume ratio of 1:1 to prepare an etching solution described as Example 19 in Table 1. Evaluations were conducted using a ruthenium film and a molybdenum film (sample pieces) prepared in the same manner as in Example 1.

### Example 20

In Example 20, the aqueous solution A4 having a pH of 13.0 and containing 0.2 mol/L of hypochlorite ions and tetramethylammonium ions was prepared using the same method as in Example 18. Further, a 0.2 mol/L orthoperiodic acid aqueous solution (hereinafter, referred to as the aqueous solution B6) having a pH of 13.0 was prepared in the same manner as in Example 9. The aqueous solution A4 and the aqueous solution B6 were mixed at a volume ratio of 1:1 to prepare an etching solution described as Example 20 in Table 1. Evaluations were conducted using a ruthenium film and a molybdenum film (sample pieces) prepared in the same manner as in Example 1.

### Comparative Example 1

In Comparative Example 1, 15 wt % HCl and ultrapure water were added to sodium hypochlorite pentahydrate to prepare a 0.01 mol/L sodium hypochlorite aqueous solution having a pH of 6.0, and evaluations were carried out using a ruthenium film and a molybdenum film (sample pieces) prepared in the same manner as in Example 1.

### Comparative Example 2

In Comparative Example 2, an etching solution containing hypobromite ions was prepared in the same manner as in Example 1 with the exception that 15 wt % of HCl was used in place of the 1 mol/L NaOH aqueous solution when adjusting the pH such that the etching solution had the composition shown in Table 1, and evaluations were carried out using a ruthenium film and a molybdenum film (sample pieces) prepared in the same manner as in Example 1.

### Comparative Example 3

In Comparative Example 3, an aqueous solution having a pH of 14.0 and containing 1.0 mol/L of hypochlorite ions was prepared in the same manner as in Example 1. A 1 mol/L NaOH aqueous solution and ultrapure water were added to didodecyldimethylammonium chloride and sodium bromide to prepare an aqueous solution having a pH of 14.0 and containing 0.00001 mol/L of didodecyldimethylammonium ions and 1.0 mol/L of bromide ions. The aqueous solution containing hypochlorite ions and the aqueous solution containing didodecyldimethylammonium ions and bromide ions were mixed at a volume ratio of 1:1 to prepare an etching solution containing hypobromite ions as described as Comparative Example 3 in Table 1. Evaluations were conducted using a ruthenium film and a molybdenum film (sample pieces) prepared in the same manner as in Example 1.

TABLE 1

| | Processing Liquid | | |
|---|---|---|---|
| | Oxidizing Agent | Onium Ion | pH |
| Example 1 | 0.5 mol/L BrO⁻ | — | 13.0 |
| Example 2 | 0.1 mol/L BrO⁻ | — | 12.5 |
| Example 3 | 0.006 mol/L BrO⁻ | tetramethylammonium ion | 9.0 |
| Example 4 | 0.01 mol/L BrO⁻ | tetramethylammonium ion | 8.0 |
| Example 5 | 0.006 mol/L BrO⁻ | tetramethylammonium ion | 10.0 |
| Example 6 | 0.015 mol/L BrO⁻ | tetramethylammonium ion | 11.0 |
| Example 7 | 0.006 mol/L BrO⁻ | tetramethylammonium ion | 11.0 |
| Example 8 | 0.008 mol/L BrO⁻ | tetramethylammonium ion | 11.0 |
| Example 9 | 0.132 mol/L orthoperiodic acid | tetramethylammonium ion | 8.0 |
| Example 10 | 0.132 mol/L orthoperiodic acid | tetramethylammonium ion | 11.0 |
| Example 11 | 0.006 mol/L BrO⁻ | tetramethylammonium and | 11.0 |
| | | tetrapropylammonium ions | |
| Example 12 | 0.5 mol/L BrO⁻ | octyltrimethylammonium ion | 12.5 |
| Example 13 | 0.01 mol/L BrO⁻ | tetramethylammonium ion and | 10.0 |
| | | octadecyltrimethylammonium ion | |
| Example 14 | 0.03 mol/L BrO⁻ | tetramethylammonium ion and | 11.0 |
| | | octyltrimethylammonium ion | |
| Example 15 | 1.0 mol/L BrO⁻ | octyltrimethylammonium ion | 13.5 |
| Example 16 | 0.2 mol/L ClO⁻ | tetramethylammonium ion | 9.5 |
| Example 17 | 0.5 mol/L BrO⁻ | ethyltrimethylammonium ion | 13.0 |
| Example 18 | 0.1 mol/L BrO⁻ | tetramethylammonium ion and | 13.0 |
| | | ethyltrimethylammonium ion | |
| Example 19 | 0.1 mol/L ClO⁻ | tetramethylammonium ion | 10.0 |
| | 0.1 mol/L orthoperiodic acid | | |
| Example 20 | 0.1 mol/L BrO⁻ | tetramethylammonium ion | 13.0 |
| | 0.1 mol/L orthoperiodic acid | | |
| Comparative | 0.01 mol/L ClO⁻ | — | 6.0 |
| Example 1 | | | |
| Comparative | 0.006 mol/L BrO⁻ | — | 7.0 |
| Example 2 | | | |
| Comparative | 0.5 mol/L BrO⁻ | didodecyldimethylammonium ion | 14.0 |
| Example 3 | | | |

TABLE 2

| | Treatment | Ru Etching Amount | | Ru Etching Rate | | | Ru | Mo Etching | Mo Etching | | Mo |
|---|---|---|---|---|---|---|---|---|---|---|---|
| | Temperature | Ratio | | [nm/min] | | | Surface | Amount Ratio | Rate [nm/min] | | Surface |
| | [° C.] | (002)/(101) | (002)/(100) | (002) | (101) | (100) | Flatness | (110)/(211) | (110) | (211) | Flatness |
| Example 1 | 10 | 7.5 | 7.3 | 87.8 | 11.7 | 12.1 | C | 8.4 | 131.1 | 15.6 | C |
| Example 2 | 25 | 5.1 | 5.0 | 91.5 | 17.8 | 18.2 | C | 6.0 | 137.3 | 22.7 | C |
| Example 3 | 25 | 3.2 | 2.9 | 10.8 | 3.4 | 3.7 | B | 4.0 | 16.2 | 4.1 | B |
| Example 4 | 10 | 6.5 | 5.9 | 15.6 | 2.4 | 2.7 | C | 6.9 | 23.4 | 3.4 | C |
| Example 5 | 10 | 4.8 | 4.3 | 5.6 | 1.2 | 1.3 | B | 4.9 | 8.4 | 1.7 | B |
| Example 6 | 40 | 2.5 | 2.3 | 18.1 | 7.2 | 7.7 | A | 3.2 | 27.2 | 8.6 | A |
| Example 7 | 65 | 2.0 | 1.7 | 28.1 | 14.0 | 16.7 | A | 2.1 | 42.1 | 19.6 | A |
| Example 8 | 90 | 1.6 | 1.8 | 73.7 | 46.1 | 42.0 | A | 1.7 | 110.6 | 64.5 | A |
| Example 9 | 55 | 3.4 | 2.9 | 15.1 | 4.4 | 5.2 | B | 3.7 | 22.7 | 6.2 | B |
| Example 10 | 55 | 7.2 | 9.0 | 14.1 | 2.0 | 1.6 | C | 7.6 | 21.2 | 2.8 | C |
| Example 11 | 25 | 2.8 | 2.5 | 11.5 | 4.1 | 4.6 | A | 3.0 | 17.3 | 5.7 | A |
| Example 12 | 25 | 2.1 | 1.8 | 45.2 | 21.4 | 25.8 | A | 2.3 | 67.8 | 30.1 | A |
| Example 13 | 25 | 1.5 | 1.4 | 4.2 | 2.8 | 3.0 | A | 1.6 | 6.3 | 3.9 | A |
| Example 14 | 65 | 1.2 | 1.1 | 19.3 | 16.1 | 17.3 | A | 1.2 | 27.0 | 22.5 | A |
| Example 15 | 25 | 2.6 | 2.8 | 12.8 | 4.9 | 4.6 | B | 2.8 | 19.2 | 6.9 | B |
| Example 16 | 25 | 1.2 | 1.4 | 17.4 | 14.5 | 12.1 | A | 1.3 | 26.1 | 20.3 | A |
| Example 17 | 25 | 4.7 | 4.8 | 87.5 | 18.8 | 18.2 | B | 5.1 | 131.3 | 25.5 | B |
| Example 18 | 25 | 4.1 | 4.3 | 12.6 | 3.1 | 2.9 | B | 4.4 | 18.9 | 4.3 | B |
| Example 19 | 25 | 7.8 | 8.6 | 25.7 | 3.3 | 3.0 | C | 8.6 | 38.6 | 4.5 | C |
| Example 20 | 25 | 5.6 | 6.0 | 58.2 | 10.4 | 9.7 | C | 5.6 | 87.3 | 15.6 | C |
| Comparative | 25 | 19.2 | 17.4 | 5.1 | 0.27 | 0.30 | D | 19.3 | 7.7 | 0.4 | D |
| Example 1 | | | | | | | | | | | |
| Comparative | 25 | 13.3 | 12.4 | 3.8 | 0.29 | 0.31 | D | 14.3 | 5.7 | 0.4 | D |
| Example 2 | | | | | | | | | | | |
| Comparative | 50 | 0.08 | 0.09 | 0.28 | 3.3 | 3.2 | D | 0.09 | 0.4 | 4.6 | D |
| Example 3 | | | | | | | | | | | |

As shown in Table 2, in the X-ray diffraction of the transition metal, when the transition metal is etched at an etching amount ratio of 0.1 or greater and 10 or less of one crystal plane of the transition metal to one other crystal plane, the difference in etching rates between the one crystal plane and the one other crystal plane can be reduced, and a decrease in flatness (surface roughness) of the transition metal surface due to etching can be suppressed.

### Example 21

### (Etching Treatment Including Washing)

60 mL of the etching solution prepared in Example 1 was prepared in a fluororesin container with a lid (94.0 mL PFA container, manufactured by As One Corporation). In addition, 60 mL of ultrapure water was prepared as a washing liquid in a fluororesin container with a lid (94.0 mL PFA container, manufactured by As One Corporation). Each sample piece with a size of 10×20 mm was immersed in the etching solution at a treatment temperature of 10° C. for one minute. After the passage of one minute, the sample piece was removed from the processing liquid and immersed in the washing liquid at a treatment temperature of 25° C. for one minute. After the passage of one minute, the sample piece was removed from the washing liquid and immersed in the etching solution at a treatment temperature of 10° C. for one minute. The etching and subsequent washing were defined as one cycle, and two cycles of treatments were carried out, after which the sample piece was washed (rinsed) with ultrapure water and dried by nitrogen blowing.

X-ray diffraction measurements were performed before the first etching and after the drying with nitrogen, the etching amount ratio was calculated by the method described in the section of (Calculation method of etching amount ratio of ruthenium (002) to any one of crystal planes of ruthenium excluding ruthenium (002)) above, and the etching rate was calculated by the method described in the section of (Calculation method of etching rate of any one of crystal planes of ruthenium excluding ruthenium (002)) above. Further, the flatness of the ruthenium surface was evaluated.

### Example 22

An etching treatment including a washing step and an evaluation were carried out in the same manner as in Example 21 with the exception of using the same etching solution (treatment temperature: 25° C.) as in Example 2 and using acetonitrile as the washing liquid.

### Example 23

An etching treatment including a washing step and an evaluation were carried out in the same manner as in Example 21 with the exception of using the same etching solution (treatment temperature: 25° C.) as in Example 2 and using 0.001 mol/L octyltrimethylammonium chloride aqueous solution as the washing liquid.

### Example 24

An etching treatment including a washing step and an evaluation were carried out in the same manner as in Example 21 with the exception of using the same etching solution (treatment temperature: 25° C.) as in Example 2 and using a 0.0005 mol/L octadecyltrimethylammonium bromide aqueous solution as the washing liquid.

### Example 25

### (Production of Processing Liquid Containing Amphoteric Surfactant)

A 31% lauryl dimethylaminoacetic acid betaine solution (product name: Amphitol 20BS, manufactured by Kao Corporation) was dissolved in ultrapure water to prepare an aqueous solution containing 10 ppm by mass of lauryl dimethylaminoacetic acid betaine, after which the pH was adjusted to 12.5 using tetramethylammonium hydroxide. Subsequently, the solution was filtered through a PTFE filter having a pore size of 20 nm to obtain a semiconductor processing liquid containing an amphoteric surfactant.

An etching treatment including a washing step and an evaluation were carried out in the same manner as in Example 21 with the exception that the same etching solution (treatment temperature: 25° C.) as in Example 2 was used and the semiconductor processing liquid containing the amphoteric surfactant (10 ppm by mass of lauryl dimethylaminoacetic acid betaine) was used as the washing liquid.

### Example 26

An etching treatment including a washing step and an evaluation were carried out in the same manner as in Example 21 with the exception that the same etching solution (treatment temperature: 25° C.) as in Example 2 was used and a 0.005 mol/L dimethyl oxalate aqueous solution was used as the washing liquid.

### Example 27

An etching treatment including a washing step and an evaluation were carried out in the same manner as in Example 21 with the exception that the same etching solution (treatment temperature: 25° C.) as in Example 2 was used and a 0.001 mol/L imidazole aqueous solution was used as the washing liquid.

### Example 28

### (Production of Processing Liquid Containing an Amine)

Glycine (available from Tokyo Chemical Industry Co., Ltd., purity >99.0%) was dissolved in ultrapure water to prepare an aqueous solution containing 50 ppm by mass of glycine, after which the pH was adjusted to 12.5 using tetramethylammonium hydroxide. Subsequently, the solution was filtered through a PTFE filter having a pore size of 20 nm to obtain a semiconductor processing liquid containing an amine.

An etching treatment including a washing step and an evaluation were carried out in the same manner as in Example 21 with the exception that the same etching solution (treatment temperature: 25° C.) as in Example 2 was used, and the semiconductor processing liquid containing 50 ppm by mass of glycine was used as the washing liquid.

### Example 29

(Production of processing liquid containing amphoteric surfactant and oxidizing agent)

According to the method described in Example 22, 1 L of a processing liquid (processing liquid containing an amphoteric surfactant) having a pH of 12.5 and containing 10 ppm by mass of lauryl dimethylaminoacetic acid betaine was produced. A 0.2 mol/L tetramethylammonium hypobromite aqueous solution (pH of 12.5) was produced by adjusting the amounts of tetramethylammonium hypochlorite and tetramethylammonium bromide used in the method described in Example 3. 30 mL of the processing liquid containing 10 ppm by mass of lauryl dimethylaminoacetic acid betaine was mixed with 30 mL of a 0.2 mol/L tetramethylammonium hypobromite aqueous solution to thereby obtain 60 mL of a processing liquid (processing liquid containing an amphoteric surfactant and an oxidizing agent) containing 5 ppm by mass of lauryl dimethylaminoacetic acid betaine and 0.1 mol/L of tetramethylammonium hypobromite. Evaluations were carried out using a ruthenium film (sample piece) prepared in the same manner as in Example 1.

### Example 30

The same etching solution and washing liquid as in Example 24 were used, and prior to the etching treatment, the sample piece was immersed in the washing liquid at a treatment temperature of 25° C. for 1 minute. The sample piece was removed from the washing liquid and immersed in the etching solution at a treatment temperature of 25° C. for one minute. The sample piece was then washed (rinsed) with ultrapure water, dried by nitrogen blowing, and then evaluated in the same manner as in Example 1.

TABLE 3

| | Processing Liquid | | | |
|---|---|---|---|---|
| | Oxidizing Agent | Onium lon | pH | Washing Liquid |
| Example 21 | 0.5 mol/L BrO⁻ | — | 13.0 | Ultrapure water |
| Example 22 | 0.1 mol/L BrO⁻ | — | 12.5 | Acetonitrile |
| Example 23 | 0.1 mol/L BrO⁻ | — | 12.5 | 0.001 mol/L Octyltrimethylammonium |
| | | | | chloride aqueous solution |
| Example 24 | 0.1 mol/L BrO⁻ | — | 12.5 | 0.0005 mol/L Octadecyltrimethylammonium |
| | | | | bromide aqueous solution |
| Example 25 | 0.1 mol/L BrO⁻ | — | 12.5 | 10 ppm by mass Lauryl dimethylaminoacetic |
| | | | | acid betaine aqueous solution |
| Example 26 | 0.1 mol/L BrO⁻ | — | 12.5 | 0.005 mol/L Dimethyl oxalate |
| | | | | aqueous solution |
| Example 27 | 0.1 mol/L BrO⁻ | — | 12.5 | 0.001 mol/L Imidazole aqueous solution |
| Example 28 | 0.1 mol/L BrO⁻ | — | 12.5 | 50 ppm by mass Glycine aqueous solution |
| Example 29 | 0.1 mol/L BrO⁻ | Tetramethylammonium and | 12.5 | — |
| | | Lauryldimethylaminoacetic | | |
| | | acid betaine | | |
| Example 30 | 0.1 mol/L BrO⁻ | — | 12.5 | 0.0005 mol/L Octadecyltrimethylammonium |
| | | | | bromide aqueous solution |

TABLE 4

| | Treatment | Ru Etching Amount | | Ru Etching Rate | | | |
|---|---|---|---|---|---|---|---|
| | Temperature | Ratio | | [nm/min] | | | Surface |
| | [° C.] | (002)/(101) | (002)/(100) | (002) | (101) | (100) | Flatness |
| Example 21 | 10 | 4.3 | 4.4 | 78.3 | 18.2 | 17.9 | B |
| Example 22 | 25 | 3.4 | 3.2 | 97.2 | 28.3 | 30.4 | A |
| Example 23 | 25 | 2.4 | 2.2 | 92.5 | 39.3 | 41.2 | A |
| Example 24 | 25 | 1.8 | 1.9 | 86.6 | 48.1 | 46.1 | A |
| Example 25 | 25 | 2.5 | 2.6 | 91.7 | 36.6 | 35.6 | A |
| Example 26 | 25 | 2.9 | 2.8 | 95.6 | 32.9 | 33.9 | A |
| Example 27 | 25 | 2.7 | 2.9 | 94.2 | 34.8 | 33.0 | A |
| Example 28 | 25 | 2.6 | 2.5 | 93.5 | 36.1 | 37.3 | A |
| Example 29 | 25 | 2.4 | 2.6 | 92.0 | 38.3 | 35.9 | A |
| Example 30 | 25 | 2.0 | 1.9 | 80.2 | 40.3 | 43.2 | A |

The compositions of the examples are shown in Table 3, and the results are shown in Table 4. As is clear from the results of Examples 21 to 28 shown in Table 4, it is found that by etching ruthenium using a method including etching and a washing step, the Ru etching amount ratio further approached 1, and thus the surface flatness after etching was further improved.

In addition, as shown by the results of Example 29 presented in Table 4, it was found that the surface flatness after etching was improved by etching ruthenium using a processing liquid containing an amphoteric surfactant and an oxidizing agent.

Further, as shown by the results of Example 30 presented in Table 4, it was found that the surface flatness after etching was improved by implementing the washing treatment before the etching treatment.

1. A processing method for a semiconductor containing a transition metal, the method comprising a step of etching the transition metal at an etching amount ratio of 0.1 or greater and 10 or less, the etching amount ratio being a ratio of an etching amount in one crystal plane of the transition metal to an etching amount in another crystal plane of the transition metal.

2. The processing method according to claim 1, comprising the step of etching and washing with a solution containing a solvent, a surfactant or a transition metal-coordinating ligand.

3. The processing method according to claim 1, wherein the transition metal is ruthenium.

4. The processing method according to claim 3, wherein the etching is a step of etching ruthenium at an etching amount ratio of 0.1 or greater and 10 or less, the etching amount ratio being a ratio of an etching amount in one crystal plane selected from the group consisting of ruthenium (002), ruthenium (100), ruthenium (101), ruthenium (110), ruthenium (102), ruthenium (103), ruthenium (200), ruthenium (112) and ruthenium (201) to an etching amount in another crystal plane different from the one crystal plane selected from the group.

5. A processing method for a ruthenium semiconductor, the method comprising a step of etching ruthenium at an etching amount ratio of 0.1 or greater and 10 or less, the etching amount ratio being a ratio of an etching amount in ruthenium (002) to an etching amount in one crystal plane of the crystal planes of ruthenium excluding ruthenium (002).

6. The processing method according to claim 3, wherein in the step of etching, an etching rate in one crystal plane of the crystal planes of ruthenium excluding ruthenium (002) is set to 1 nm/min or greater and 100 nm/min or less.

7. The processing method according to claim 1, wherein the one crystal plane of the crystal planes of ruthenium excluding ruthenium (002) is ruthenium (101) or ruthenium (100).

8. The processing method according to claim 1, wherein the step of etching is performed by wet etching using an etching solution, and the etching solution comprises an onium ion.

9. (canceled)

10. The processing method according to claim 8, wherein the onium ion is an ammonium ion.

11. The processing method according to claim 8, wherein the etching solution comprises an oxidizing agent selected from a halogen oxyacid, a halogen oxyacid ion, a halogen oxyacid salt, a permanganic acid, a permanganate ion, a permanganate salt, a cerium (N) salt, a ferricyanide salt, hydrogen peroxide and ozone.

12. The processing method according to claim 11, wherein a concentration of the oxidizing agent in the etching solution is 0.001 mol/L or greater and 1 mol/L or less.

13. (canceled)

14. The processing method according to claim 11, wherein the halogen oxyacid ion is a hypobromite ion, and a pH of the etching solution at 25° C. is 8 or greater and 13.5 or less.

15. The processing method according to claim 8, wherein the etching solution comprises:
at least one type of hypohalite ion; and
at least one type of anionic species selected from a halate ion, a halite ion, and a halide ion, and
a content of at least one type of anionic species of the anionic species is 0.30 mol/L or greater and 6.00 mol/L or less.

16. The processing method according to claim 1, further comprising a step of removing a transition metal oxide generated by the step of etching.

17. The processing method according to claim 16, wherein the step of removing the transition metal oxide is a step of washing with a solution containing a solvent, a surfactant or a transition metal-coordinating ligand.

18. The processing method according to claim 16, wherein the transition metal is ruthenium.

19. A method for processing a semiconductor containing a transition metal, the method comprising: a step of etching the transition metal; and a step of measuring an etching amount ratio, the etching amount ratio being a ratio of an etching amount in one crystal plane of the transition metal to an etching amount in another crystal plane of the transition metal.

20. The processing method according to claim 19, wherein the step of measuring the etching amount ratio of an etching amount in one crystal plane of the transition metal to an etching amount in another crystal plane of the transition metal is a step in which an X-ray diffraction measurement is used.

21. A method for producing a semiconductor containing a transition metal, the method comprising the processing method according to claim 1.

22-25. (canceled)

26. The processing method according to claim 5, wherein in the step of etching, an etching rate in one crystal plane of the crystal planes of ruthenium excluding ruthenium (002) is set to 1 nm/min or greater and 100 nm/min or less.

27. The processing method according to claim 5, wherein the one crystal plane of the crystal planes of ruthenium excluding ruthenium (002) is ruthenium (101) or ruthenium (100).

28. The processing method according to claim 5, wherein the step of etching is performed by wet etching using an etching solution, and the etching solution comprises an onium ion.

29. The processing method according to claim 28, wherein the onium ion is an ammonium ion.

30. A method for producing a semiconductor containing a transition metal, the method comprising the processing method according to claim 5.

31. A method for producing a semiconductor containing a transition metal, the method comprising the processing method according to claim 19.
